(19) United States
(12) Patent Application Publication
(10) Pub. No.: US 2010/0317136 A1
(43) Pub. Date: Dec. 16, 2010

(54) METHOD FOR PRODUCING SEMICONDUCTOR LIGHT EMITTING DEVICE, METHOD FOR PRODUCING SEMICONDUCTOR DEVICE, METHOD FOR PRODUCING DEVICE, METHOD FOR GROWING NITRIDE TYPE III-V GROUP COMPOUND SEMICONDUCTOR LAYER, METHOD FOR GROWING SEMICONDUCTOR LAYER, AND METHOD FOR GROWING LAYER

(75) Inventors: Katsunori Yanashima, Kanagawa (JP); Kensaku Motoki, Osaka (JP)

Correspondence Address: SNR DENTON US LLP, P.O. BOX 061080, CHICAGO, IL, 60606-1080, US

(73) Assignees: SUMITOMO ELECTRIC INDUSTRIES, LTD, Osaka (JP); SONY CORPORATION, Tokyo (JP)

(21) Appl. No.: 12/824,593

(22) Filed: Jun. 28, 2010

Related U.S. Application Data
(62) Division of application No. 11/279,709, filed on Apr. 13, 2006.
Application No. 11/279,709 is a division of application No. 10/813,371, filed on Mar. 30, 2004, now abandoned.

(51) Int. Cl. H01L 33/30

(52) U.S. Cl. 438/46; 257/E33.023

(57) ABSTRACT

A method for producing a semiconductor light emitting device is disclosed. The method comprises the step of growing a nitride type III-V group compound semiconductor layer that forms a light emitting device structure on a principal plane of a nitride type III-V group compound semiconductor substrate on which a plurality of second regions made of a crystal having a second average dislocation density are regularly arranged in a first region made of a crystal having a first average dislocation density so as to produce a semiconductor light emitting device, the second average dislocation density being greater than the first average dislocation density. The nitride type III-V group compound semiconductor layer does not directly contact the second regions on the principal plane of the nitride type III-V group compound semiconductor substrate.

### RELATED APPLICATION DATA

This application is a division of U.S. patent application Ser. No. 11/279,709, filed Apr. 13, 2006, which is a division of U.S. patent application Ser. No. 10/813,371, filed Mar. 30, 2004, both of which are incorporated herein by reference to the extent permitted by law.

### BACKGROUND OF THE INVENTION

1. Field of the Invention

The present invention relates to a method for producing a semiconductor light emitting device, a method for producing a semiconductor device, a method for producing a device, a method for growing a nitride type III-V group compound semiconductor layer, a method for growing a semiconductor layer, and a method for growing a layer. In particular, the present invention relates to for example those suitable for producing a semiconductor laser, a light emitting diode, or an electron traveling device using a nitride type III-V group compound semiconductor.

2. Description of the Related Art

Nitride type III-V group compound semiconductors such as GaN, AlGaN, GaInN, and AlGaInN feature in a large band gap Eg and direct transition semiconductor materials in comparison with arsenic type III-V group compound semiconductors such as AlGaInAs and phosphorous type III-V group compound semiconductors such as AlGaInP. Thus, these nitride type III-V group compound semiconductors has attracted considerable attention as materials of semiconductor lasers that can emit short wavelength light ranging from ultraviolet ray to green and materials of semiconductor light emitting devices such as light emitting diodes (LEDs) that can cover a wide range of light emitting wavelength from ultraviolet ray to red and white. These materials are expected for wide applications such as high density optical discs, full color displays, environmental and medical fields.

In addition, these nitride type III-V group compound semiconductors for example GaN feature in a large saturation speed in a high electric field, a high temperature operation of for example up to around 400° C., and continuous crystal growth for a semiconductor layer and an insulation layer using AlN in for example a metal-insulator-semiconductor (MIS) structure. Thus, these nitride type III-V group compound semiconductors are expected for materials that compose radio frequency electronic devices that can operate at high temperature and with a large output.

In addition, these nitride type III-V group compound semiconductors have the following advantages.

(1) Since they have higher thermal conductivities than GaAs type semiconductors, they are suitable for devices that operate at high temperatures and with large outputs.

(2) Since they are chemically stable and hard, they have high reliability.

(3) They are compound semiconductor materials that less contaminate environment. In other words, AlGaInN type semiconductors do not contain environmental pollutants and poisonous substances. In reality, they do not contain arsenic (As) for AlGaAs type semiconductors, cadmium (Cd) for ZnCdSSe type semiconductors, and a material arsine (AsH₃).

However, proper substrate materials for devices using nitride type III-V group compound semiconductors that have high reliability are not known.

To obtain high quality crystals, substrate materials for nitride type III-V group compound semiconductors have the following problems and conditions to be solved and satisfied.

(1) Structural materials GaN, AlGaN, and GaInN of the nitride type III-V group compound semiconductors are of full distortion type of which there are different lattice constants. Thus, compositions, thicknesses, and so forth of nitride type III-V group compound semiconductors and substrates should be designed so that they are free from cracks and obtain good crystal films.

(2) A high quality substrate that can lattice-match GaN has not been developed. Like a high quality GaAs substrate that can lattice-match a GaAs type semiconductor and a GaInP type semiconductor and a high quality InP substrate that can lattice-match a GaInAs type semiconductor, for example a high quality GaN substrate is under development. A SiC substrate having a small difference of lattice constants is expensive. In addition, it is difficult to produce a SiC substrate having a large diameter. Since a tensile distortion takes place in a crystal film, it easily cracks. In addition, there is no substrate that can lattice-match GaN.

(3) Necessary conditions of substrate materials for nitride type III-V group compound semiconductors are a high crystal growth temperature of around 1000° C. and no deterioration and no corrosion of V group materials in an ammonium atmosphere.

In consideration of the foregoing reasons, as a substrate of a nitride type III-V group compound semiconductor, a sapphire substrate is often used.

A sapphire substrate is stable at crystal growth temperature of a nitride type III-V group compound semiconductor. Thus, as an advantage, high quality substrates of two inches or three inches can be stably supplied. However, lattice-mismatch of a sapphire substrate to GaN is large (around 13%). Thus, a buffer layer made of GaN or AlN is grown on the sapphire substrate at low temperature. Above the buffer layer, a nitride type III-V group compound semiconductor is grown. As a result, although a single crystal of a nitride type III-V group compound semiconductor can be grown, the defect density is as large as 10⁸ to 10⁹ (cm⁻²) due to lattice mismatching. Thus, when the nitride type III-V group compound semiconductor is used for a semiconductor laser, it does not have reliability for a long time.

In addition, (1) since a sapphire substrate does not have cleavage, an end plane of a laser cannot be stably formed with specular property. (2) Since sapphire is insulative, it is necessary to take out a p-side electrode and an n-side electrode from the upper surface of the substrate. (3) When a crystal growth film is thick, due to the difference of thermal expansion coefficients of a nitride type III-V group compound semiconductor and sapphire, the substrate largely skews at room temperature. As a result, the device forming process is adversely affected.

To obtain a high quality semiconductor crystal that is grown on a substrate such as a sapphire substrate whose lattice constant is different from the semiconductor crystal, a method using epitaxial lateral overgrowth (ELO) is known. In the ELO, high crystal quality regions (lateral growth regions) and low crystal quality regions (or high defect density regions) (on seed crystals, their boundaries, meeting portions, and so forth) periodically take place. However, when the size of an active region (for example, a light emitting region of a light emitting device or an electron traveling region of an electron traveling device) is not large, the period of the ELO can be greater than the interval of stripes of a semiconductor laser and the interval of emitter region region/collector region (or source region/drain region) of a transistor. For example, the period of the ELO is 10 to 20 μm, whereas the size of the active region of a device is around several μm. Thus, the active region can be designed in the high quality region.

When a device is formed on a sapphire substrate by the ELO, in addition to the foregoing problem of bad cleavage due to characteristics of sapphire, there are for example the following problems.

(1) Since the number of steps necessary for the ELO is large, the yield decreases.

(2) Since the crystal film thickness increases for the ELO, the substrate largely skews due to thermal stress. As a result, the controllabilities of the crystal growing step and wafer process deteriorate.

(3) The device size is restricted. A device such as an LED, a photo detector (PD), or an integrated circuit device that has an active region greater than the ELO period (namely, one side of the active region is for example several hundred μm), since all the device region cannot be formed as high crystal quality regions, the effect of the ELO cannot be fully obtained.

Although the foregoing problems would be solved when a high quality GaN substrate could be obtained. However, so far, a high quality GaN substrate having a large diameter has not been obtained. This is because a good seed crystal cannot be obtained from GaN by hydride vapor phase epitaxy (HVPE), which is high temperature (high pressure) growth. Thus, single crystal growth cannot be stably performed. As a result, a high quality substrate cannot be easily produced.

Japanese Patent Laid-Open Publication No. 2001-102307 has proposed a method for producing a single crystal GaN substrate that allows the foregoing problems to be solved. According to the related art, after a GaN seed substrate having a high defect density is formed, a three-dimensional facet (referred to as core) is formed on a part thereof. A crystal is grown so that the facet is not closed. Crystal dislocations are gathered around the core portion. As a result, a wide substrate having high quality is produced.

However, the technology that has been disclosed in Japanese Patent Laid-Open Publication No. 2001-102307 causes the through-dislocations to be gathered around a region of a growth layer so as to decease the through-dislocations of the other regions. Thus, a low defect density region (core) and high defect density regions coexist in the obtained single crystal GaN substrate. In addition, the location of the high defect density regions cannot be controlled. Instead, the high defect density regions randomly take place. Thus, when a semiconductor device for example a semiconductor laser is produced, a nitride type III-V group compound semiconductor layer is grown on a single crystal GaN substrate. At that point, a high defect density region cannot be prevented from being formed in a light emitting region. As a result, light emitting characteristics and reliability of the semiconductor laser deteriorate.

### OBJECTS AND SUMMARY OF THE INVENTION

Therefore, in view of the foregoing, it would be desirable to provide a semiconductor light emitting device that has good characteristics such as good light emitting characteristic, high reliability, and long life and to provide a method for easily producing such a semiconductor light emitting device.

More generally, it would be desirable to provide a semiconductor device that has good characteristics, high reliability, and long life and to provide a method for easily producing such a semiconductor device.

Further more generally, it would be desirable to provide a variety of types of devices that have good characteristics, high reliabilities, and long lives and to provide a method for easily producing such devices.

In addition, it would be desirable to provide a semiconductor light emitting device that has good characteristics such as good light emitting characteristic, high reliability, and long life or methods for growing a nitride type III-V group compound semiconductor layer, a semiconductor layer, and a layer suitable for producing a semiconductor device that has good characteristics, high reliability, and long life or various types of devices that have good characteristics, high reliabilities, and long lives.

The inventors of the present invention intensively studied the foregoing problems and obtained the following result. The obtained result will be described in brief.

The inventors improved the technology disclosed in Japanese Patent Laid-Open Publication No. 2001-102307 and succeeded in controlling the positions of high defect density regions that take place in a low defect density region. In other words, high defect density regions are not gathered while a crystal is being grown. Instead, a seed crystal or the like is artificially, circularly and regularly (for example periodically) formed on a proper substrate such as a GaAs substrate. On the seed crystal, a crystal is grown so as to control the positions of the high defect density regions. As a result, the crystal quality can be improved and a good crystal region can be widened. In this case, by arranging a seed crystal or the like, a pattern of the high defect density regions can be freely changed.

In this case, the seed crystal or the like is for example a polycrystal, an amorphous substance, a single crystal of GaN, a nitride type III-V group compound semiconductor such as AlGaInN other than GaN, or a material other than a nitride type III-V group compound semiconductor. However, as long as the seed crystal or the like is a core that defines the position at which crystal defects gather, the structure of the seed crystal or the like is not restricted.

When a semiconductor light emitting device such as a semiconductor laser, more generally, a semiconductor device is produced using such a substrate, it is necessary to prevent high defect density regions on the substrate from adversely affecting the device. In other words, when a semiconductor layer is grown on a substrate, defects of high defect density regions on a base substrate propagates to the semiconductor layer. Thus, it is necessary to prevent the characteristics of the device and the reliability thereof from deteriorating due to the defects.

In the case that it is difficult to obtain a substrate that has a low defect density and whose material is the same as a semiconductor used for a device, when the semiconductor layer is grown on the substrate, such a problem also takes place. More generally, in the case that it is difficult to obtain a substrate whose material is the same as a device, when a layer is grown on the substrate, such a problem takes place.

The inventors of the present invention studied various techniques and finally found out an effective technique that can solve the foregoing problems. Finally, the inventors devised the present invention.

In other words, to solve the foregoing problem, a first aspect of the present invention is a method for producing a semiconductor light emitting device, comprising the step of growing a nitride type III-V group compound semiconductor layer that forms a light emitting device structure on a principal plane of a nitride type III-V group compound semiconductor substrate on which a plurality of second regions made of a crystal having a second average dislocation density are regularly arranged in a first region made of a crystal having a first average dislocation density so as to produce a semiconductor light emitting device, the second average dislocation density being greater than the first average dislocation density,

wherein the nitride type III-V group compound semiconductor layer does not directly contact the second regions on the principal plane of the nitride type III-V group compound semiconductor substrate.

To prevent the nitride type III-V group compound semiconductor layer from directly contacting the second regions on the principal plane of the nitride type III-V group compound semiconductor substrate, before the nitride type III-V group compound semiconductor layer is grown, at least part of the second regions is removed from the principal plane of the nitride type III-V group compound semiconductor substrate. More practically, before the nitride type III-V group compound semiconductor layer is grown, the second regions are removed from the principal plane of the nitride type III-V group compound semiconductor substrate for a predetermined depth. In this case, the predetermined depth is selected in accordance with the structure of the device composed of the nitride type III-V group compound semiconductor layer, the growing condition of the nitride type III-V group compound semiconductor layer, and so forth. Generally, the predetermined depth is 1 μm or greater. Preferably, the predetermined depth is around the thickness of the device composed of the nitride type III-V group compound semiconductor layer or greater (for example, 10 μm or greater). Before the nitride type III-V group compound semiconductor layer is grown, all the second regions may be removed from the principal plane of the nitride III-V group compound semiconductor substrate. The second regions are removed typically by etching. In reality, the second regions are removed by wet-etching, dry-etching, thermochemically-etching, ion-milling, or the like.

To prevent the nitride type III-V group compound semiconductor layer from directly contacting the second regions on the principal plane of the nitride type III-V group compound semiconductor substrate, before the nitride type III-V group compound semiconductor layer is grown, the front surface of the second regions may be coated with a coating layer. As the coating layer, various types can be used as long as they can withstand the growing temperature. Practically, as the coating layer, an insulation film such as a SiO₂ film, a SiₓN_{y} film, or a SOG (Spin on Glass) film, a metal film having a high melting point such as tungsten (W), molybdenum (Mo), or tantalum (Ta), or a nitride film thereof can be used. In this case, only the coating layer may be formed in the second regions. When the second regions are removed from the principal plane of the nitride type III-V group compound semiconductor substrate for the predetermined depth, the removed portions of the second regions may be filled with the coating layer. In the former, the front surface of the coating layer is higher than the principal plane of the nitride type III-V group compound semiconductor substrate. In the latter, by using an etch-back technique or the like, the front surface of the coating layer may be matched with the principal plane of the nitride type III-V group compound semiconductor substrate.

The interval of two adjacent second regions or the arrangement period of the second regions is selected in accordance with the size of the device. Generally, the interval or arrangement period is 20 μm or greater, 50 μm or greater, or 100 μm or greater. The upper limit of the interval or arrangement period of the second regions is not clearly defined. However, generally, the interval or arrangement period of the second regions is around 1000 μm. The second regions typically pierce a nitride type III-V group compound semiconductor substrate. The second regions are typically formed in an irregular polygonal prism shape. Third regions may be disposed between the first region and the second regions, the third regions having a third average dislocation density that is greater than the first average dislocation density and lower than the second average dislocation density. In this case, the nitride type III-V group compound semiconductor layer does not directly contact the second regions on the principal plane of the nitride type III-V group compound semiconductor substrate. Preferably, the nitride type III-V group compound semiconductor layer does not directly contact the second regions and the third regions on the principal plane of the nitride type III-V group compound semiconductor substrate. In the latter case, practically, before the nitride type III-V group compound semiconductor layer is grown, at least part of the second regions and the third regions is removed from the principal plane of the nitride type III-V group compound semiconductor substrate.

The diameter of each of the second regions is typically 10 μm or greater and 100 μm or smaller. The diameter of each of the second regions is more typically 20 μm or greater and 50 μm or smaller. When the third regions are disposed, the diameter of each of the third regions is typically greater than the diameter of each of the second regions by 20 μm or greater and 200 μm or smaller. The diameter of each of the third regions is more typically greater than the diameter of each of the second regions by 40 μm or greater and 160 μm or smaller. The diameter of each of the third regions is most typically greater than the diameter of each of the second regions by 60 μm or greater and 140 μm or smaller.

The average dislocation density of each of the second regions is generally five times greater than the average dislocation density of the first region.

The average dislocation density of the first region is 2×10⁶ cm⁻² or smaller and the average dislocation density of each of the second regions is 1×10⁸ cm⁻² or greater. When the third regions are disposed, the average dislocation density of each of the third regions is typically 1×10⁸ cm⁻² or smaller and 2×10⁶ cm⁻² or greater.

To prevent the second regions that have a high average dislocation density from adversely affecting the light emitting region of the semiconductor light emitting device, the light emitting region is spaced apart from the second regions by 1 μm or greater, preferably 10 μm or greater, more preferably 100 μm or greater. When there are third regions, most preferably the light emitting region of the semiconductor light emitting device does not contain the second regions and the third regions. More practically, the semiconductor light emitting device is a semiconductor laser or a light emitting diode. When the semiconductor light emitting device is a semiconductor laser, a region in which a drive current flows through a stripe shaped electrode is preferably spaced apart from the second regions by 1 μm or greater, more preferably by 10 μm or greater, further more preferably by 100 μm or greater. When there are third regions, most preferably, a region in which the drive current flows through a stripe shaped electrode does not contain the second regions and the third region. The number of stripe shaped electrodes, namely the number of laser stripes, may be one or plurality. The width of the stripe shaped electrode can be selected as required.

The nitride type III-V group compound semiconductor substrate or the nitride type III-V group compound semiconductor layer is most generally made of AlₓB_{y}Ga_{1-x-y-z}In_{z}AsᵤN₁₋ᵤ₋ᵥPᵥ (where 0≦x≦1, 0≦y≦1, 0≦z≦1, 0≦u≦1, 0≦v≦1, 0≦x+y+z<1, 0≦u+v<1). The nitride type III-V group compound semiconductor substrate or the nitride type III-V group compound semiconductor layer is more practically made of AlₓB_{y}Ga_{1-x-y-z}In_{z}N (where 0≦x≦1, 0y≦1, 0≦z≦1, 0≦x+y+z<1). The nitride type III-V group compound semiconductor substrate or the nitride type III-V group compound semiconductor layer is typically made of AlₓGa_{1-x-z}In_{z}N (where 0≦x≦1, 0≦z≦1). The nitride type III-V group compound semiconductor substrate is most typically made of GaN.

The description for the first aspect of the present invention applies to the other aspects unless that is contrary to characteristics of the other aspects.

A second aspect of the present invention is a method for producing a semiconductor light emitting device, comprising the step of:

growing a nitride type III-V group compound semiconductor layer that forms a light emitting device structure on a principal plane of a nitride type III-V group compound semiconductor substrate of which a plurality of second regions are regularly arranged in a first region so as to produce a semiconductor light emitting device, the first region being made of a crystal having a first average defect density, the plurality of second regions having a second average defect density that is greater than the first average defect density,

wherein the nitride type III-V group compound semiconductor layer does not directly contact the second regions on the principal plane of the nitride type III-V group compound semiconductor substrate.

The “average defect density” represents an average density of all lattice defects that adversely affect characteristics and reliability of a device. The defects include all types of defects such as dislocation, stacking defect, and point defect (this definition applies to the description that follows).

A third aspect of the present invention is a method for producing a semiconductor light emitting device, comprising the step of:

growing a nitride type III-V group compound semiconductor layer that forms a light emitting device structure on a principal plane of a nitride type III-V group compound semiconductor substrate of which a plurality of second regions made of a crystal are regularly arranged in a first region made of a crystal so as to produce a semiconductor light emitting device, the crystallinity of the second regions being worse than the crystallinity of the first region,

wherein the nitride type III-V group compound semiconductor layer does not directly contact the second regions on the principal plane of the nitride type III-V group compound semiconductor substrate.

Typically, the first region made of a crystal is a single crystal. The second regions whose crystallinity is worse than the first region is a single crystal, an amorphous substance, or a mixture of at least two thereof (this definition applied to the description that follows). This corresponds to the case that the average dislocation density or average defect density of the second regions is greater than that of the first region.

A fourth aspect of the present invention is a method for producing a semiconductor device, comprising the step of:

growing a nitride type III-V group compound semiconductor layer that forms a device structure on a principal plane of a nitride type III-V group compound semiconductor substrate on which a plurality of second regions made of a crystal having a second average dislocation density are regularly arranged in a first region made of a crystal having a first average dislocation density so as to produce a semiconductor device, the second average dislocation density being greater than the first average dislocation density,

wherein the nitride type III-V group compound semiconductor layer does not directly contact the second regions on the principal plane of the nitride type III-V group compound semiconductor substrate.

A fifth aspect of the present invention is a method for producing a semiconductor device, comprising the step of:

growing a nitride type III-V group compound semiconductor layer that forms a device structure on a principal plane of a nitride type III-V group compound semiconductor substrate on which a plurality of second regions made of a crystal having a second average defect density are regularly arranged in a first region made of a crystal having a first average defect density so as to produce a semiconductor device, the second average dislocation density being greater than the first average dislocation density,

wherein the nitride type III-V group compound semiconductor layer does not directly contact the second regions on the principal plane of the nitride type III-V group compound semiconductor substrate.

A sixth aspect of the present invention is a method for producing a semiconductor device, comprising the step of:

growing a nitride type III-V group compound semiconductor layer that forms a device structure on a principal plane of a nitride type III-V group compound semiconductor substrate on which a plurality of second regions made of a crystal are regularly arranged in a first region made of a crystal so as to produce a semiconductor device, the crystallinity of the second regions being worse than the crystallinity of the first region,

wherein the nitride type III-V group compound semiconductor layer does not directly contact the second regions on the principal plane of the nitride type III-V group compound semiconductor substrate.

According to the fourth aspect to sixth aspect of the present invention, the semiconductor device includes a light emitting device such as a light emitting diode, a semiconductor laser, or the like, a photo detector, a field effect transistor (FET) such as a high electron mobility transistor, and an electron traveling device such as a hetero junction bipolar transistor (HBT) (this definition applies to the description that follows).

According to the fourth aspect to sixth aspect of the present invention, the active region of the semiconductor device is spaced apart from the second regions by preferably 1 μm or greater, more preferably 10 μm or greater, further preferably 100 μm or greater so as to prevent the second regions from adversely affecting the active region of the semiconductor device. When there are third regions, most preferably the active region of the semiconductor device does not contain the second regions and the third region. The active region represents a light emitting region of a semiconductor light emitting device, a light receiving region of a semiconductor photo detector, and an electron traveling region of an electron traveling device (this definition applies to the description that follows).

A seventh aspect of the present invention is a method for producing a semiconductor light emitting device, comprising the step of:

growing a semiconductor layer that forms a light emitting device structure on a principal plane of a semiconductor substrate on which a plurality of second regions made of a crystal having a second average dislocation density are regularly arranged in a first region made of a crystal having a first average dislocation density so as to produce a semiconductor light emitting device, the second average dislocation density being greater than the first average dislocation density,

wherein the semiconductor layer does not directly contact the second regions on the principal plane of the semiconductor substrate.

An eighth aspect of the present invention is a method for producing a semiconductor light emitting device, comprising the step of:

growing a semiconductor layer that forms a light emitting device structure on a principal plane of a semiconductor substrate on which a plurality of second regions made of a crystal having a second average defect density are regularly arranged in a first region made of a crystal having a first average defect density so as to produce a semiconductor light emitting device, the second average defect density being greater than the first average dislocation density,

wherein the semiconductor layer does not directly contact the second regions on the principal plane of the semiconductor substrate.

A ninth aspect of the present invention is a method for producing a semiconductor light emitting device, comprising the step of:

growing a semiconductor layer that forms a light emitting device structure on a principal plane of a semiconductor substrate on which a plurality of second regions made of a crystal are regularly arranged in a first region made of a crystal so as to produce a semiconductor light emitting device, the crystallinity of the second regions being worse than the crystallinity of the first region,

wherein the semiconductor layer does not directly contact the second regions on the principal plane of the semiconductor substrate.

A tenth aspect of the present invention is a method for producing a semiconductor device, comprising the step of:

growing a semiconductor layer that forms a device structure on a principal plane of a semiconductor substrate on which a plurality of second regions made of a crystal having a second average dislocation density are regularly arranged in a first region made of a crystal having a first average dislocation density so as to produce a semiconductor device, the second average dislocation density being greater than the first average dislocation density,

wherein the semiconductor layer does not directly contact the second regions on the principal plane of the semiconductor substrate.

An eleventh aspect of the present invention is a method for producing a semiconductor device, comprising the step of:

growing a semiconductor layer that forms a device structure on a principal plane of a semiconductor substrate on which a plurality of second regions made of a crystal having a second average defect density are regularly arranged in a first region made of a crystal having a first average defect density so as to produce a semiconductor device, the second average defect density being greater than the first average dislocation density.

wherein the semiconductor layer does not directly contact the second regions on the principal plane of the semiconductor substrate.

A twelfth aspect of the present invention is a method for producing a semiconductor device, comprising the step of:

growing a semiconductor layer that forms a device structure on a principal plane of a semiconductor substrate on which a plurality of second regions made of a crystal are regularly arranged in a first region made of a crystal so as to produce a semiconductor device, the crystallinity of the second regions being worse than the crystallinity of the first region,

wherein the semiconductor layer does not directly contact the second regions on the principal plane of the semiconductor substrate.

According to the tenth aspect to twelfth aspect of the present invention, the material of the semiconductor substrate or the semiconductor layer is a nitride type III-V group compound semiconductor, another semiconductor having a wurtzit structure, more generally a hexagonal crystal structure for example ZnO, α-ZnS, α-CdS, or α-CdSe, or various types of semiconductors having other crystal structures.

A thirteenth aspect of the present invention is a method for producing a device, comprising the step of:

growing a layer that forms a device structure on a principal plane of a substrate on which a plurality of second regions made of a crystal having a second average dislocation density are regularly arranged in a first region made of a crystal having a first average dislocation density so as to produce a device, the second average dislocation density being greater than the first average dislocation density,

wherein the layer does not directly contact the second regions on the principal plane of the substrate.

A fourteenth aspect of the present invention is a method for producing a device, comprising the step of:

growing a layer that forms a device structure on a principal plane of a substrate on which a plurality of second regions made of a crystal having a second average defect density are regularly arranged in a first region made of a crystal having a first average defect density so as to produce a device, the second average defect density being greater than the first average dislocation density,

wherein the layer does not directly contact the second regions on the principal plane of the substrate.

A fifteenth aspect of the present invention is a method for producing a device, comprising the step of:

growing a layer that forms a device structure on a principal plane of a substrate on which a plurality of second regions made of a crystal are regularly arranged in a first region made of a crystal so as to produce a device, the crystallinity of the second regions being worse than the crystallinity of the first region,

wherein the layer does not directly contact the second regions on the principal plane of the substrate.

According to the thirteenth aspect to fifteenth aspect of the present invention, the device is a semiconductor device (for example, a light emitting device, a photo detector, or an electron traveling device), a piezoelectric device, an electricity collecting device, an optical device (for example, a secondary higher harmonic wave generating device), a dielectric device (including a ferrodielectric device), a superconductive device, or the like. In this case, as the material of the substrate or layer, the foregoing various types of semiconductors can be used. As the material of a piezoelectric device, an electricity collecting device, an optical device, a dielectric device, or a superconductive device, various types of materials (for example, an oxide) can be used. As the material of the oxide, many types of materials for example disclosed in Journal of the Society of Japan, Vol. 103, No. 11 (1995), pp. 1099-1111 and Materials Science and Engineering, B41 (1996) pp. 166-173 can be used.

A sixteenth aspect of the present invention is a method for producing a semiconductor light emitting device, comprising the step of:

growing a nitride type III-V group compound semiconductor layer that forms a light emitting device structure on a principal plane of a nitride type III-V group compound semiconductor substrate on which a plurality of second regions made of a crystal having a second average dislocation density are regularly arranged in a first region made of a crystal having a first average dislocation density so as to produce a semiconductor light emitting device, the second average dislocation density being greater than the first average dislocation density, the second regions being arranged at a first interval in a first direction and at a second interval in a second direction perpendicular to the first direction, the second interval being smaller than the first interval,

wherein the nitride type III-V group compound semiconductor layer does not directly contact the second regions on the principal plane of the nitride type III-V group compound semiconductor substrate.

A seventeenth aspect of the present invention is a method for producing a semiconductor light emitting device, comprising the step of:

growing a nitride type III-V group compound semiconductor layer that forms a light emitting device structure on a principal plane of a nitride type III-V group compound semiconductor substrate on which a plurality of second regions made of a crystal having a second average defect density are regularly arranged in a first region made of a crystal having a first average defect density so as to produce a semiconductor light emitting device, the second average defect density being greater than the first average defect density, the second regions being arranged at a first interval in a first direction and at a second interval in a second direction perpendicular to the first direction, the second interval being smaller than the first interval,

wherein the nitride type III-V group compound semiconductor layer does not directly contact the second regions on the principal plane of the nitride type III-V group compound semiconductor substrate.

An eighteenth aspect of the present invention is a method for producing a semiconductor light emitting device, comprising the step of:

growing a nitride type III-V group compound semiconductor layer that forms a light emitting device structure on a principal plane of a nitride type III-V group compound semiconductor substrate on which a plurality of second regions made of a crystal are regularly arranged in a first region made of a crystal so as to produce a semiconductor light emitting device, the crystallinity of the second regions being worse than the crystallinity of the first region, the second regions being arranged at a first interval in a first direction and at a second interval in a second direction perpendicular to the first direction, the second interval being smaller than the first interval,

wherein the nitride type III-V group compound semiconductor layer does not directly contact the second regions on the principal plane of the nitride type III-V group compound semiconductor substrate.

A nineteenth aspect of the present invention is a method for producing a semiconductor light emitting device, comprising the step of:

growing a nitride type III-V group compound semiconductor layer that forms a light emitting device structure on a principal plane of a nitride type III-V group compound semiconductor substrate on which a plurality of second regions that linearly extend and that are made of a crystal having a second average dislocation density are regularly arranged in parallel in a first region made of a crystal having a first average dislocation density so as to produce a semiconductor light emitting device, the second average dislocation density being greater than the first average dislocation density,

wherein the nitride type III-V group compound semiconductor layer does not directly contact the second regions on the principal plane of the nitride type III-V group compound semiconductor substrate.

A twentieth aspect of the present invention is a method for producing a semiconductor light emitting device, comprising the step of:

growing a nitride type III-V group compound semiconductor layer that forms a light emitting device structure on a principal plane of a nitride type III-V group compound semiconductor substrate on which a plurality of second regions that linearly extend and that are made of a crystal having a second average defect density are regularly arranged in parallel in a first region made of a crystal having a first average defect density so as to produce a semiconductor light emitting device, the second average defect density being greater than the first average defect density,

wherein the nitride type III-V group compound semiconductor layer does not directly contact the second regions on the principal plane of the nitride type III-V group compound semiconductor substrate.

A twenty first aspect of the present invention is a method for producing a semiconductor light emitting device, comprising the step of:

growing a nitride type III-V group compound semiconductor layer that forms a light emitting device structure on a principal plane of a nitride type III-V group compound semiconductor substrate on which a plurality of second regions that linearly extend and that are made of a crystal are regularly arranged in parallel in a first region made of a crystal so as to produce a semiconductor light emitting device, the crystallinity of the second regions being worse than the crystallinity of the first region,

wherein the nitride type III-V group compound semiconductor layer does not directly contact the second regions on the principal plane of the nitride type III-V group compound semiconductor substrate.

A twenty second aspect of the present invention is a method for producing a semiconductor device, comprising the step of:

growing a nitride type III-V group compound semiconductor layer that forms a device structure on a principal plane of a nitride type III-V group compound semiconductor substrate on which a plurality of second regions made of a crystal having a second average dislocation density are regularly arranged in a first region made of a crystal having a first average dislocation density so as to produce a semiconductor device, the second average dislocation density being greater than the first average dislocation density, the second regions being arranged at a first interval in a first direction and at a second interval in a second direction perpendicular to the first direction, the second interval being smaller than the first interval,

wherein the nitride type III-V group compound semiconductor layer does not directly contact the second regions on the principal plane of the nitride type III-V group compound semiconductor substrate.

A twenty third aspect of the present invention is a method for producing a semiconductor device, comprising the step of:

growing a nitride type III-V group compound semiconductor layer that forms a device structure on a principal plane of a nitride type III-V group compound semiconductor substrate on which a plurality of second regions made of a crystal having a second average defect density are regularly arranged in a first region made of a crystal having a first average defect density so as to produce a semiconductor device, the second average defect density being greater than the first average defect density, the second regions being arranged at a first interval in a first direction and at a second interval in a second direction perpendicular to the first direction, the second interval being smaller than the first interval,

wherein the nitride type III-V group compound semiconductor layer does not directly contact the second regions on the principal plane of the nitride type III-V group compound semiconductor substrate.

A twenty fourth aspect of the present invention is a method for producing a semiconductor device, comprising the step of:

growing a nitride type III-V group compound semiconductor layer that forms a device structure on a principal plane of a nitride type III-V group compound semiconductor substrate on which a plurality of second regions made of a crystal are regularly arranged in a first region made of a crystal so as to produce a semiconductor device, the crystallinity of the second regions being worse than the crystallinity of the first region, the second regions being arranged at a first interval in a first direction and at a second interval in a second direction perpendicular to the first direction, the second interval being smaller than the first interval,

wherein the nitride type III-V group compound semiconductor layer does not directly contact the second regions on the principal plane of the nitride type III-V group compound semiconductor substrate.

A twenty fifth aspect of the present invention is a method for producing a semiconductor device, comprising the step of:

growing a nitride type III-V group compound semiconductor layer that forms a device structure on a principal plane of a nitride type III-V group compound semiconductor substrate on which a plurality of second regions that linearly extend and that are made of a crystal having a second average dislocation density are regularly arranged in parallel in a first region made of a crystal having a first average dislocation density so as to produce a semiconductor device, the second average dislocation density being greater than the first average dislocation density,

wherein the nitride type III-V group compound semiconductor layer does not directly contact the second regions on the principal plane of the nitride type III-V group compound semiconductor substrate.

A twenty sixth aspect of the present invention is a method for producing a semiconductor device, comprising the step of:

growing a nitride type III-V group compound semiconductor layer that forms a device structure on a principal plane of a nitride type III-V group compound semiconductor substrate on which a plurality of second regions that linearly extend and that are made of a crystal having a second average defect density are regularly arranged in parallel in a first region made of a crystal having a first average defect density so as to produce a semiconductor device, the second average defect density being greater than the first average defect density,

wherein the nitride type III-V group compound semiconductor layer does not directly contact the second regions on the principal plane of the nitride type III-V group compound semiconductor substrate.

A twenty seventh aspect of the present invention is a method for producing a semiconductor device, comprising the step of:

growing a nitride type III-V group compound semiconductor layer that forms a device structure on a principal plane of a nitride type III-V group compound semiconductor substrate on which a plurality of second regions that linearly extend and that are made of a crystal are regularly arranged in parallel in a first region made of a crystal so as to produce a semiconductor device, the crystallinity of the second regions being worse than the crystallinity of the first region,

wherein the nitride type III-V group compound semiconductor layer does not directly contact the second regions on the principal plane of the nitride type III-V group compound semiconductor substrate.

A twenty eighth aspect of the present invention is a method for producing a semiconductor light emitting device, comprising the step of:

growing a semiconductor layer that forms a light emitting device structure on a principal plane of a semiconductor substrate on which a plurality of second regions made of a crystal having a second average dislocation density are regularly arranged in a first region made of a crystal having a first average dislocation density so as to produce a semiconductor light emitting device, the second average dislocation density being greater than the first average dislocation density, the second regions being arranged at a first interval in a first direction and at a second interval in a second direction perpendicular to the first direction, the second interval being smaller than the first interval,

wherein the semiconductor layer does not directly contact the second regions on the principal plane of the semiconductor substrate.

A twenty ninth aspect of the present invention is a method for producing a semiconductor light emitting device, comprising the step of:

growing a semiconductor layer that forms a light emitting device structure on a principal plane of a semiconductor substrate on which a plurality of second regions made of a crystal having a second average defect density are regularly arranged in a first region made of a crystal having a first average defect density so as to produce a semiconductor light emitting device, the second average defect density being greater than the first average defect density, the second regions being arranged at a first interval in a first direction and at a second interval in a second direction perpendicular to the first direction, the second interval being smaller than the first interval,

wherein the semiconductor layer does not directly contact the second regions on the principal plane of the semiconductor substrate.

A thirtieth aspect of the present invention is a method for producing a semiconductor light emitting device, comprising the step of: growing a semiconductor layer that forms a light emitting device structure on a principal plane of a semiconductor substrate on which a plurality of second regions made of a crystal are regularly arranged in a first region made of a crystal so as to produce a semiconductor light emitting device, the crystallinity of the second regions being worse than the crystallinity of the first region, the second regions being arranged at a first interval in a first direction and at a second interval in a second direction perpendicular to the first direction, the second interval being smaller than the first interval,

wherein the semiconductor layer does not directly contact the second regions on the principal plane of the semiconductor substrate.

A thirty first aspect of the present invention is a method for producing a semiconductor light emitting device, comprising the step of:

growing a semiconductor layer that forms a light emitting device structure on a principal plane of a semiconductor substrate on which a plurality of second regions that linearly extend and that are made of a crystal having a second average dislocation density are regularly arranged in parallel in a first region made of a crystal having a first average dislocation density so as to produce a semiconductor light emitting device, the second average dislocation density being greater than the first average dislocation density,

wherein the semiconductor layer does not directly contact the second regions on the principal plane of the semiconductor substrate.

A thirty second aspect of the present invention is a method for producing a semiconductor light emitting device, comprising the step of:

growing a semiconductor layer that forms a light emitting device structure on a principal plane of a semiconductor substrate on which a plurality of second regions that linearly extend and that are made of a crystal having a second average defect density are regularly arranged in parallel in a first region made of a crystal having a first average defect density so as to produce a semiconductor light emitting device, the second average defect density being greater than the first average defect density,

wherein the semiconductor layer does not directly contact the second regions on the principal plane of the semiconductor substrate.

A thirty third aspect of the present invention is a method for producing a semiconductor light emitting device, comprising the step of:

growing a semiconductor layer that forms a light emitting device structure on a principal plane of a semiconductor substrate on which a plurality of second regions that linearly extend and that are made of a crystal are regularly arranged in parallel in a first region made of a crystal so as to produce a semiconductor light emitting device, the crystallinity of the second regions being worse than the crystallinity of the first region,

wherein the semiconductor layer does not directly contact the second regions on the principal plane of the semiconductor substrate.

A thirty fourth aspect of the present invention is a method for producing a semiconductor device, comprising the step of:

growing a semiconductor layer that forms a device structure on a principal plane of a semiconductor substrate on which a plurality of second regions made of a crystal having a second average dislocation density are regularly arranged in a first region made of a crystal having a first average dislocation density so as to produce a semiconductor device, the second average dislocation density being greater than the first average dislocation density, the second regions being arranged at a first interval in a first direction and at a second interval in a second direction perpendicular to the first direction, the second interval being smaller than the first interval,

wherein the semiconductor layer does not directly contact the second regions on the principal plane of the semiconductor substrate.

A thirty fifth aspect of the present invention is a method for producing a semiconductor device, comprising the step of:

growing a semiconductor layer that forms a device structure on a principal plane of a semiconductor substrate on which a plurality of second regions made of a crystal having a second average defect density are regularly arranged in a first region made of a crystal having a first average defect density so as to produce a semiconductor device, the second average defect density being greater than the first average defect density, the second regions being arranged at a first interval in a first direction and at a second interval in a second direction perpendicular to the first direction, the second interval being smaller than the first interval,

wherein the semiconductor layer does not directly contact the second regions on the principal plane of the semiconductor substrate.

A thirty sixth aspect of the present invention is a method for producing a semiconductor device, comprising the step of:

growing a semiconductor layer that forms a device structure on a principal plane of a semiconductor substrate on which a plurality of second regions made of a crystal are regularly arranged in a first region made of a crystal so as to produce a semiconductor device, the crystallinity of the second regions being worse than the crystallinity of the first region, the second regions being arranged at a first interval in a first direction and at a second interval in a second direction perpendicular to the first direction, the second interval being smaller than the first interval,

wherein the semiconductor layer does not directly contact the second regions on the principal plane of the semiconductor substrate.

A thirty seventh aspect of the present invention is a method for producing a semiconductor device, comprising the step of:

growing a semiconductor layer that forms a device structure on a principal plane of a semiconductor substrate on which a plurality of second regions that linearly extend and that are made of a crystal having a second average dislocation density are regularly arranged in parallel in a first region made of a crystal having a first average dislocation density so as to produce a semiconductor device, the second average dislocation density being greater than the first average dislocation density,

wherein the semiconductor layer does not directly contact the second regions on the principal plane of the semiconductor substrate.

A thirty eighth aspect of the present invention is a method for producing a semiconductor device, comprising the step of:

growing a semiconductor layer that forms a device structure on a principal plane of a semiconductor substrate on which a plurality of second regions that linearly extend and that are made of a crystal having a second average defect density are regularly arranged in parallel in a first region made of a crystal having a first average defect density so as to produce a semiconductor device, the second average defect density being greater than the first average defect density,

wherein the semiconductor layer does not directly contact the second regions on the principal plane of the semiconductor substrate.

A thirty ninth aspect of the present invention is a method for producing a semiconductor device, comprising the step of:

growing a semiconductor layer that forms a device structure on a principal plane of a semiconductor substrate on which a plurality of second regions that linearly extend and that are made of a crystal are regularly arranged in parallel in a first region made of a crystal so as to produce a semiconductor device, the crystallinity of the second regions being worse than the crystallinity of the first region,

wherein the semiconductor layer does not directly contact the second regions on the principal plane of the semiconductor substrate.

A fortieth aspect of the present invention is a method for producing a device, comprising the step of:

growing a layer that forms a device structure on a principal plane of a substrate on which a plurality of second regions made of a crystal having a second average dislocation density are regularly arranged in a first region made of a crystal having a first average dislocation density so as to produce a device, the second average dislocation density being greater than the first average dislocation density, the second regions being arranged at a first interval in a first direction and at a second interval in a second direction perpendicular to the first direction, the second interval being smaller than the first interval,

wherein the layer does not directly contact the second regions on the principal plane of the substrate.

A forty first aspect of the present invention is a method for producing a device, comprising the step of:

growing a layer that forms a device structure on a principal plane of a substrate on which a plurality of second regions made of a crystal having a second average defect density are regularly arranged in a first region made of a crystal having a first average defect density so as to produce a device, the second average defect density being greater than the first average defect density, the second regions being arranged at a first interval in a first direction and at a second interval in a second direction perpendicular to the first direction, the second interval being smaller than the first interval,

wherein the layer does not directly contact the second regions on the principal plane of the substrate.

A forty second aspect of the present invention is a method for producing a device, comprising the step of:

growing a layer that forms a device structure on a principal plane of a substrate on which a plurality of second regions made of a crystal are regularly arranged in a first region made of a crystal so as to produce a device, the crystallinity of the second regions being worse than the crystallinity of the first region, the second regions being arranged at a first interval in a first direction and at a second interval in a second direction perpendicular to the first direction, the second interval being smaller than the first interval,

wherein the layer does not directly contact the second regions on the principal plane of the substrate.

A forty third aspect of the present invention is a method for producing a device, comprising the step of:

growing a layer that forms a device structure on a principal plane of a substrate on which a plurality of second regions that linearly extend and that are made of a crystal having a second average dislocation density are regularly arranged in parallel in a first region made of a crystal having a first average dislocation density so as to produce a device, the second average dislocation density being greater than the first average dislocation density,

wherein the layer does not directly contact the second regions on the principal plane of the substrate.

A forty fourth aspect of the present invention is a method for producing a device, comprising the step of:

growing a layer that forms a device structure on a principal plane of a substrate on which a plurality of second regions that linearly extend and that are made of a crystal having a second average defect density are regularly arranged in parallel in a first region made of a crystal having a first average defect density so as to produce a device, the second average defect density being greater than the first average defect density,

wherein the layer does not directly contact the second regions on the principal plane of the substrate.

A forty fifth aspect of the present invention is a method for producing a device, comprising the step of:

growing a layer that forms a device structure on a principal plane of a substrate on which a plurality of second regions that linearly extend and that are made of a crystal are regularly arranged in parallel in a first region made of a crystal so as to produce a device, the crystallinity of the second regions being worse than the crystallinity of the first region,

wherein the layer does not directly contact the second regions on the principal plane of the substrate.

According to the sixteenth aspect to forty fifth aspect of the present invention, the interval (first interval) of the second regions in the first direction or the interval of the second regions that linearly extend is the same as the interval of the second regions or the arrangement interval of the second regions according to the first aspect of the present invention. In addition, the interval (first interval) of the second regions in the first direction or the interval of the second regions that linearly extend is the same as the interval of the second regions or the arrangement interval of the second regions according to the first aspect of the present invention except that the former is typically 50 μm or greater. According to the sixteenth aspect to eighteenth aspect, the twenty second aspect to twenty fourth aspect, the twenty eighth aspect to thirty aspect, the thirty fourth aspect to thirty sixth aspect, and the fortieth aspect to forty second aspect, the interval of the second regions in the second direction can be freely selected so that the interval of the second regions is smaller than the first interval. The interval of the second regions depends on the size of each of the second regions, generally 10 μm or greater and 1000 μm or smaller, typically, 20 μm or greater and 200 μm or smaller. In addition, in a chip region (hereinafter referred to as device region) that is formed by scrubbing the substrate, the number of rows of second regions in the second direction or the number of second regions that linearly extend is substantially not greater than seven. The maximum number of rows of second regions in the second direction or the maximum number of second regions that linearly extend is seven because the device region may contain seven second regions depending on the relation between the number of rows of second regions in the second direction or the interval of second regions that linearly extend and the chip size of the device. The number of rows of second regions in the second direction or the number of second regions that linearly extend of a semiconductor light emitting device is typically three or less.

The description for the first aspect to fifteenth aspect of the present invention applies to the sixteenth aspect to forty fifth aspect unless that is contrary to characteristics thereof.

A forty sixth aspect of the present invention is a method for growing a nitride type III-V group compound semiconductor layer on a principal plane of a nitride type III-V group compound semiconductor substrate on which a second region made of a crystal having a second average dislocation density is contained in a first region made of a crystal having a first average dislocation density, the second average dislocation density being greater than the first average dislocation density,

wherein the nitride type III-V group compound semiconductor layer does not directly contact the second region on the principal plane of the nitride type III-V group compound semiconductor substrate.

A forty seventh aspect of the present invention is a method for growing a nitride type III-V group compound semiconductor layer on a principal plane of a nitride type III-V group compound semiconductor substrate on which a second region made of a crystal having a second average defect density is contained in a first region made of a crystal having a first average defect density, the second average defect density being greater than the first average defect density,

wherein the nitride type III-V group compound semiconductor layer does not directly contact the second region on the principal plane of the nitride type III-V group compound semiconductor substrate.

A forty eighth aspect of the present invention is a method for growing a nitride type III-V group compound semiconductor layer on a principal plane of a nitride type III-V group compound semiconductor substrate on which a second region made of a crystal is contained in a first region made of a crystal, the crystallinity of the second region being worse than the crystallinity of the first region,

wherein the nitride type III-V group compound semiconductor layer does not directly contact the second region on the principal plane of the nitride type III-V group compound semiconductor substrate.

A forty ninth aspect of the present invention is a method for growing a semiconductor layer on a principal plane of a semiconductor substrate on which a second region made of a crystal having a second average dislocation density is contained in a first region made of a crystal having a first average dislocation density, the second average dislocation density being greater than the first average dislocation density,

wherein the semiconductor layer does not directly contact the second region on the principal plane of the semiconductor substrate.

A fiftieth aspect of the present invention is a method for growing a semiconductor layer on a principal plane of a semiconductor substrate on which a second region made of a crystal having a second average defect density is contained in a first region made of a crystal having a first average defect density, the second average defect density being greater than the first average defect density,

wherein the semiconductor layer does not directly contact the second region on the principal plane of the semiconductor substrate.

A fifty first aspect of the present invention is a method for growing a semiconductor layer on a principal plane of a semiconductor substrate on which a second region made of a crystal is contained in a first region made of a crystal, the crystallinity of the second region being worse than the crystallinity of the first region,

wherein the semiconductor layer does not directly contact the second region on the principal plane of the semiconductor substrate.

A fifty second aspect of the present invention is a method for growing a layer on a principal plane of a substrate on which a second region made of a crystal having a second average dislocation density is contained in a first region made of a crystal having a first average dislocation density, the second average dislocation density being greater than the first average dislocation density,

wherein the layer does not directly contact the second region on the principal plane of the substrate.

A fifty third aspect of the present invention is a method for growing a layer on a principal plane of a substrate on which a second region made of a crystal having a second average defect density is contained in a first region made of a crystal having a first average defect density, the second average defect density being greater than the first average defect density,

wherein the layer does not directly contact the second region on the principal plane of the substrate.

A fifty fourth aspect of the present invention is a method for growing a layer on a principal plane of a substrate on which a second region made of a crystal is contained in a first region made of a crystal, the crystallinity of the second region being worse than the crystallinity of the first region,

wherein the layer does not directly contact the second region on the principal plane of the substrate.

According to the forty sixth aspect to fifty fourth aspect of the present invention, the materials of the nitride type III-V group compound semiconductor substrate, the nitride type III-V group compound semiconductor layer, the semiconductor substrate, the semiconductor layer, the substrate, and the layer are the same as those according to the first aspect to fifteenth aspect of the present invention.

According to the present invention, since the nitride type III-V group compound semiconductor layer, the semiconductor layer, or the layer made of various types of materials that forms a light emitting device structure or a device structure does not directly contact the second regions on the principal plane of the nitride type III-V group compound semiconductor substrate, the semiconductor substrate, or the substrate, respectively, the average dislocation density, the average defect density, or the crystallinity of the second regions being greater or worse than that of the first region. As a result, the nitride type III-V group compound semiconductor layer, the semiconductor layer, or the layer made of various types of materials that forms the light emitting device structure or device structure can be prevented from being adversely affected by the second regions.

These and other objects, features and advantages of the present invention will become more apparent in light of the following detailed description of a best mode embodiment thereof, as illustrated in the accompanying drawings.

### BRIEF DESCRIPTION OF THE DRAWINGS

FIG. 1A and FIG. 1B are a perspective view and a sectional view showing a GaN substrate according to a first embodiment of the present invention.

FIG. 2 is a plan view showing the GaN substrate according to the first embodiment of the present invention.

FIG. 3 is a schematic diagram showing an example of a distribution of dislocation densities near a region B of the GaN substrate according to the first embodiment of the present invention.

FIG. 4 is a sectional view describing an example compared with the first embodiment of the present invention.

FIG. 5 is a sectional view describing the example compared with the first embodiment of the present invention.

FIG. 6 is a sectional view showing the GaN substrate according to the first embodiment of the present invention.

FIG. 7 is a sectional view showing a state of which a GaN type semiconductor layer is grown on the GaN substrate according to the first embodiment of the present invention.

FIG. 8 is a sectional view describing a method for producing a GaN type semiconductor laser according to the first embodiment of the present invention.

FIG. 9 is a sectional view describing the method for producing the GaN type semiconductor laser according to the first embodiment of the present invention.

FIG. 10 is a plan view describing the method for producing the GaN type semiconductor laser according to the first embodiment of the present invention.

FIG. 11 is a sectional view describing the method for producing the GaN type semiconductor laser according to the first embodiment of the present invention.

FIG. 12 is a sectional view showing a GaN substrate according to a second embodiment of the present invention.

FIG. 13 is a sectional view showing a state of which a GaN type semiconductor layer is grown on the GaN substrate according to the second embodiment of the present invention.

FIG. 14 is a sectional view showing a state of which a GaN type semiconductor layer is grown on a GaN substrate according to a third embodiment of the present invention.

FIG. 15 is a sectional view showing a state of which a GaN type semiconductor layer is grown on a GaN substrate according to a fourth embodiment of the present invention.

FIG. 16 is a sectional view showing a GaN substrate according to a fifth embodiment of the present invention.

FIG. 17 is a sectional view showing a state of which a GaN type semiconductor layer is grown on the GaN substrate according to the fifth embodiment of the present invention.

FIG. 18 is a sectional view showing a state of which a GaN type semiconductor layer is grown on a GaN substrate according to a sixth embodiment of the present invention.

FIG. 19 is a sectional view showing the state of which the GaN type semiconductor layer is grown on the GaN substrate according to the sixth embodiment of the present invention.

FIG. 20 is a sectional view describing a method for producing a GaN substrate according to a seventh embodiment of the present invention.

FIG. 21 is a sectional view describing the method for producing the GaN substrate according to the seventh embodiment of the present invention.

FIG. 22 is a sectional view showing a GaN substrate according to an eight embodiment of the present invention.

FIG. 23 is a sectional view showing a GaN substrate according to a ninth embodiment of the present invention.

FIG. 24 is a sectional view describing a method for producing a GaN substrate according to a tenth embodiment of the present invention.

FIG. 25 is a sectional view describing the method for producing the GaN substrate according to the tenth embodiment of the present invention.

FIG. 26 is a sectional view describing the method for producing the GaN substrate according to the tenth embodiment of the present invention.

FIG. 27 is a plan view showing a GaN substrate according to an eleventh embodiment of the present invention.

FIG. 28 is a sectional view describing a method for producing a GaN type semiconductor laser according to a twenty first embodiment of the present invention.

FIG. 29 is a plan view describing a method for producing a GaN type semiconductor laser according to a twenty second embodiment of the present invention.

FIG. 30 is a plan view describing a method for producing a GaN type semiconductor laser according to a twenty third embodiment of the present invention.

FIG. 31 is a plan view describing the method for producing the GaN type semiconductor laser according to the twenty third embodiment of the present invention.

FIG. 32 is a plan view describing a method for producing a GaN type semiconductor laser according to a twenty forth embodiment of the present invention.

FIG. 33 is a plan view describing a method for producing a GaN type semiconductor laser according to a twenty fifth embodiment of the present invention.

FIG. 34 is a plan view describing a method for producing a GaN type semiconductor laser according to a twenty sixth embodiment of the present invention.

FIG. 35 is a plan view describing a method for producing a GaN type semiconductor laser according to a twenty seventh embodiment of the present invention.

FIG. 36 is a plan view describing a method for producing a GaN type semiconductor laser according to a twenty eighth embodiment of the present invention.

FIG. 37 is a plan view describing a method for producing a GaN type semiconductor laser according to a twenty ninth embodiment of the present invention.

FIG. 38 is a plan view describing the method for producing the GaN type semiconductor laser according to the twenty ninth embodiment of the present invention.

FIG. 39 is a plan view describing a method for producing a GaN type semiconductor laser according to a thirtieth embodiment of the present invention.

FIG. 40 is a plan view describing a method for producing a GaN type semiconductor laser according to a thirty first embodiment of the present invention.

FIG. 41 is a plan view describing a method for producing a GaN type semiconductor laser according to a thirty second embodiment of the present invention.

FIG. 42 is a plan view describing a method for producing a GaN type semiconductor laser according to a thirty third embodiment of the present invention.

FIG. 43 is a plan view describing a method for producing a GaN type semiconductor laser according to a thirty fourth embodiment of the present invention.

### DETAILED DESCRIPTION OF THE PREFERRED EMBODIMENTS

Next, with reference to the accompanying drawings, embodiments of the present invention will be described. In all drawings showing the embodiments of the present invention, same or corresponding portions will be denoted by same reference numerals.

### First Embodiment

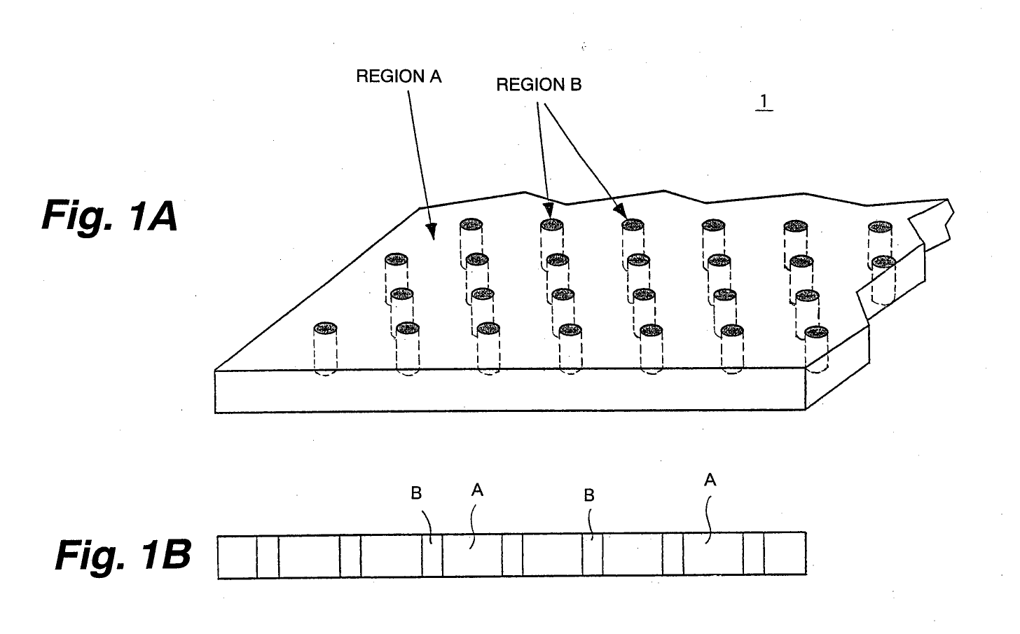

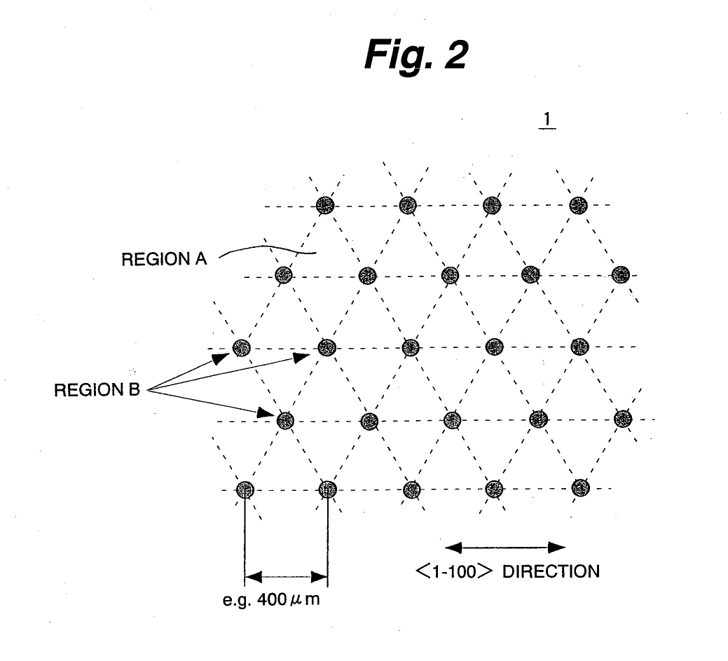

FIG. 1A, FIG. 1B, and FIG. 2 show a GaN substrate 1 according to a first embodiment of the present invention. FIG. 1A is a perspective view showing the GaN substrate 1. FIG. 1B is a sectional view showing regions B in the most adjacent direction of the GaN substrate 1. FIG. 2 is a plan view showing the GaN substrate 1. The GaN substrate 1 is made of an n-type transistor and has a (0001) plane (C plane) orientation. However, the GaN substrate 1 may have an R plane orientation, an A plane orientation, or an M plane orientation. The GaN substrate 1 has a region A and regions B. The region A is made of a crystal having a low average dislocation density. The regions B are made of a crystal having a high average dislocation density. The regions B are periodically arranged in the region A in a hexagonal lattice shape. The regions B generally have an irregular polygonal prism shape. For simplicity, FIG. 1A shows the regions B in a cylinder shape (this applies to the description that follows). In this case, a straight line that connects the most adjacent regions B accords with a <1-100> direction of GaN and its equivalent direction. Alternatively, a straight line that connects the most adjacent regions B may accord with a <11-20> direction of GaN and its equivalent direction. The regions B pierce the GaN substrate 1. The thickness of the GaN substrate 1 is for example in the range from 200 to 600 μm. In FIG. 2, dotted lines represent only relative relations of the regions B, not real (physical) lines (this applies to the description that follows).

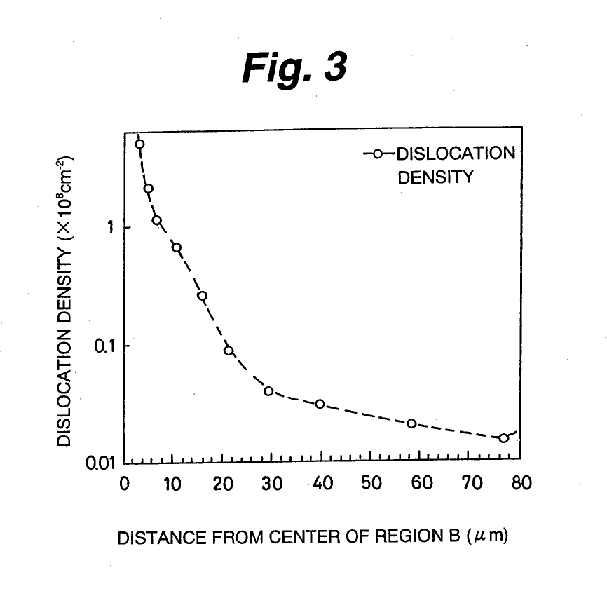

The arrangement period of the regions B (for example, the interval between the centers of the most adjacent regions B) is for example 400 μm and the diameter thereof is for example 20 μm. The average dislocation density of the region A is for example 2×10⁶ cm⁻². The average dislocation density of the regions B is for example 1×10⁸ cm⁻². FIG. 3 shows an example of a distribution of dislocation densities in the radius direction from the center of each region B.

The GaN substrate 1 can be produced by a crystal growing technology as follows.

The GaN substrate 1 is produced by the following crystal growing mechanism. A crystal is grown on a facet plane that is an inclined plane. The crystal is continuously grown on the inclined facet plane so as to propagate dislocations and gather them to a predetermined position. The region in which the crystal has been grown on the facet plane and from which dislocations have been propagated becomes a low density defect region. At a lower portion of the inclined facet plane, the crystal is grown and becomes a high density defect region having a clear boundary. The dislocations gather at the boundary of the high density defect region or the inside thereof. As a result, the dislocations disappear or stay at the boundary of the high density defect region or the inside thereof.

The shape of the facet plane depends on the shape of the high density defect region. When the defect region is formed in a dot shape, the facet plane surrounds the bottom of the dot and forms a pit. When the defect region is formed in a stripe shape, the facet plane is formed in a triangular prism shape of which the stripe is placed at the bottom and inclined facet planes are placed on both the sides of the stripe.

Thereafter, the front surface of the grown layer is ground and abraded. As a result, the front surface of the grown layer is smoothened so that the GaN substrate 1 can be used as a substrate.

The foregoing high density defect region may have several states. For example, the high density defect region may be made of a polycrystal. Alternatively, the high density defect region may be made of a single crystal that is slightly inclined against the adjacent low density defect region. Alternatively, the high density defect region may have an inverted C axis against the adjacent low density defect region. Thus, since the high density defect region has a clear boundary against the low density defect region, they are distinguished from each other.

By growing the crystal with the high density defect region, the crystal can be grown with the adjacent facet plane that is not buried.

When a crystal of GaN is grown on a base substrate, the high density defect region can be formed with a seed. The seed is for example a layer of an amorphous substance or a layer of a polycrystal. By growing GaN on the seed, the high density defect region can be formed.

The GaN substrate 1 can be practically produced in the following manner. First of all, a base substrate is prepared. As the base substrate, various types of substrates can be used. Although a sapphire substrate may be used, since it is not easily removed at a later step, it is preferable to use a GaAs substrate that can be easily removed. Thereafter, a seed made of for example a SiO₂ film is formed on the base substrate. The seed can be formed in a dot shape or a stripe shape. Many seeds can be regularly formed. More practically, in this case, seeds are formed in accordance with the arrangement of the regions B shown in FIG. 2. Thereafter, GaN is grown as a thick film by for example hydride vapor phase expitaxy (HYPE). After GaN is grown, a facet plane is formed in accordance with a pattern of seeds. When seeds are formed in a dot shaped pattern according to the first embodiment, pits composed of the facet plane are regularly formed. In contrast, when seeds are formed in a stripe shaped pattern, a prism shaped facet plane is formed.

Thereafter, the base substrate is removed. The thick film layer of GaN is ground and abraded so as to flatten the front surface thereof. As a result, the GaN substrate 1 can be produced. The thickness of the GaN substrate 1 can be freely designated.

The GaN substrate 1 produced in the foregoing manner has a principal plane that is the C plane. On the principal plane, a dot shaped (or stripe shaped) high density defect region that has a predetermined size, namely regions B, are regularly formed. The dislocation density of the single crystal region other than the regions B, namely the region A, is lower than that of the regions B.

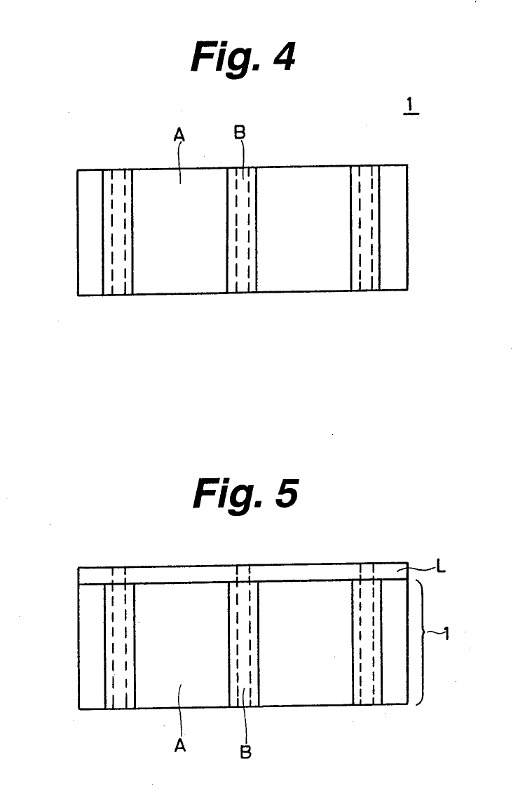

FIG. 4 shows the dislocations of the regions B of the GaN substrate 1 with broken lines. When a GaN type semiconductor layer L as shown in FIG. 5 is grown on the GaN substrate 1, dislocations are propagated from the regions B of the GaN substrate 1 to the GaN type semiconductor layer L. As a result, the quality of the GaN type semiconductor layer L deteriorates.

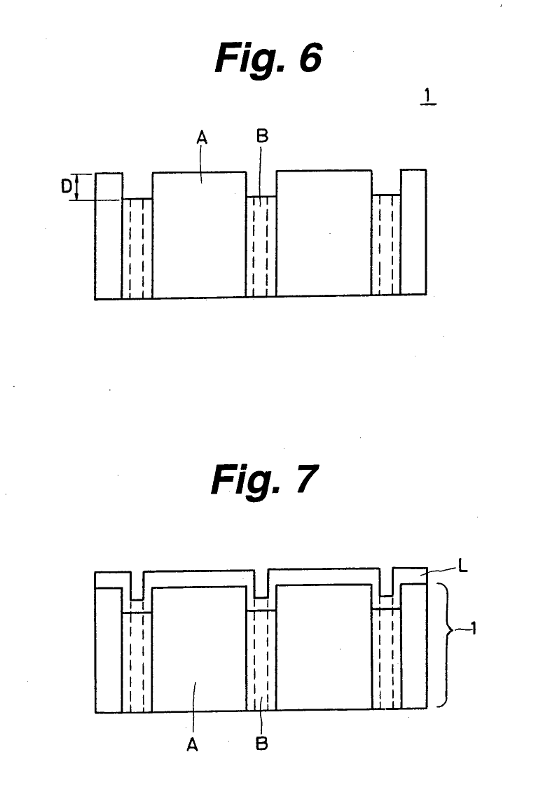

To solve such a problem, according to the first embodiment, as shown in FIG. 6, upper portions of the regions B are etched out by a depth D. The depth D is for example in the range from 1 to 10 μm. Thus, the front surface of the regions B can be sufficiently spaced apart from the principal plane of the GaN substrate 1. Thereafter, as shown in FIG. 7, a GaN type semiconductor layer L that forms a device structure is grown on the GaN substrate 1 by the metal organic chemical vapor deposition (MOCVD) method or the like. Dislocations are propagated from the regions B to a portion grown on the regions B of the GaN type semiconductor layer L. However, since the dislocations are propagated to a limited region, the GaN type semiconductor layer L grown on the principal plane of the GaN substrate 1 can be prevented from being adversely affected by such a region.

The regions B can be etched in the following manner. Generally, nitride type III-V group compound semiconductors such as GaN are chemically stable. Thus, except for strong alkalis such as sodium hydroxide and acids such as strong hydrochloric acid and phosphoric acid at high temperature, the nitride type III-V group compound semiconductor semiconductors are not wet-etched at room temperature. However, generally, the dislocation density of the regions B of the GaN substrate 1 is much greater than that of the region A thereof. The bonding state of atoms of the crystal of the regions B that have a high defect density is imperfect in comparison with that of the region A. Thus, the etching speed of the regions B is greater than that of the region A that is nearly a perfect crystal. Thus, the regions B can be selectively etched against the region A. The regions B may be etched by masking the front surface of the region. Alternatively, by fully etching the front surface of the GaN substrate 1, only the regions B can be selectively etched. To increase the etching speed, the temperature of the etching solution may be raised. The etching solution may be potassium hydroxide (KOH) as an alkali solution or phosphoric acid as an acid. As a practical example of the etching method, a KOH solution placed in an etching tank is heated and kept at 75° C. A GaN substrate 1 is soaked in the KOH solution for 10 minutes. After the GaN substrate 1 has been etched, the GaN substrate 1 is removed from the etching tank. The GaN substrate 1 is rinsed with pure water. The GaN substrate 1 is dried by blowing dried nitrogen. By the etching, the regions B can be removed for a depth of around 5 μm. At that point, to prevent the rear surface of the GaN substrate 1 from being etched and becoming rough, a Ti/Pt film of which a Ti film for 20 nm and a Pt film for 300 nm have been laminated may be formed as a protection film by the vacuum evaporation method or the like. Thereafter, the GaN substrate 1 may be etched. The Ti/Pt film may be etched out by for example aqua regia.

The regions B may be etched by dry etching such as reactive ion etching (RIE) as well as the foregoing wet etching. Alternatively, the regions B may be thermo-chemically etched by heating and keeping the regions B at a temperature of 800° C. or higher in a hydrogen atmosphere, an ammonium atmosphere, or the like.

Next, a practical example of a process for producing a GaN type semiconductor laser using a GaN substrate 1 shown in FIG. 6 will be described. In the following, GaN type semiconductor lasers that have a ridge structure and a separate confinement hetero-structure will be described.

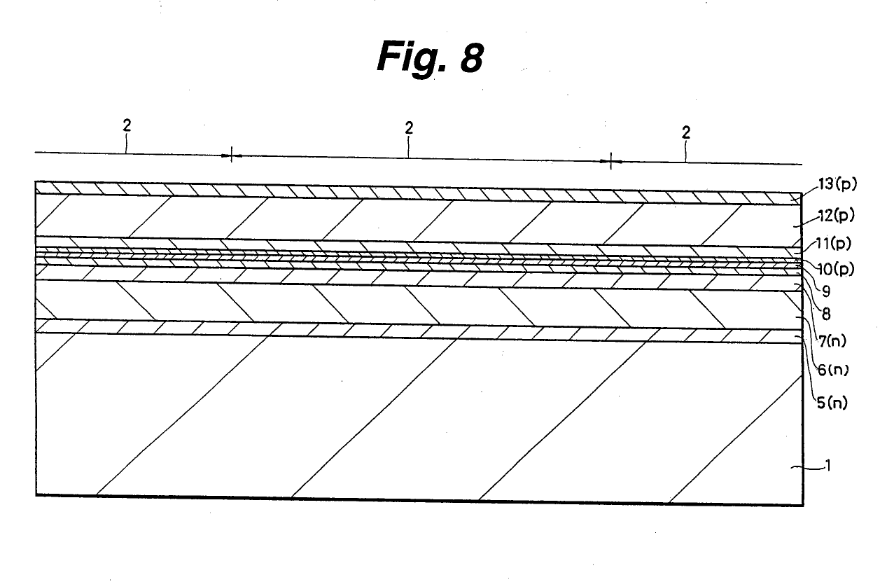

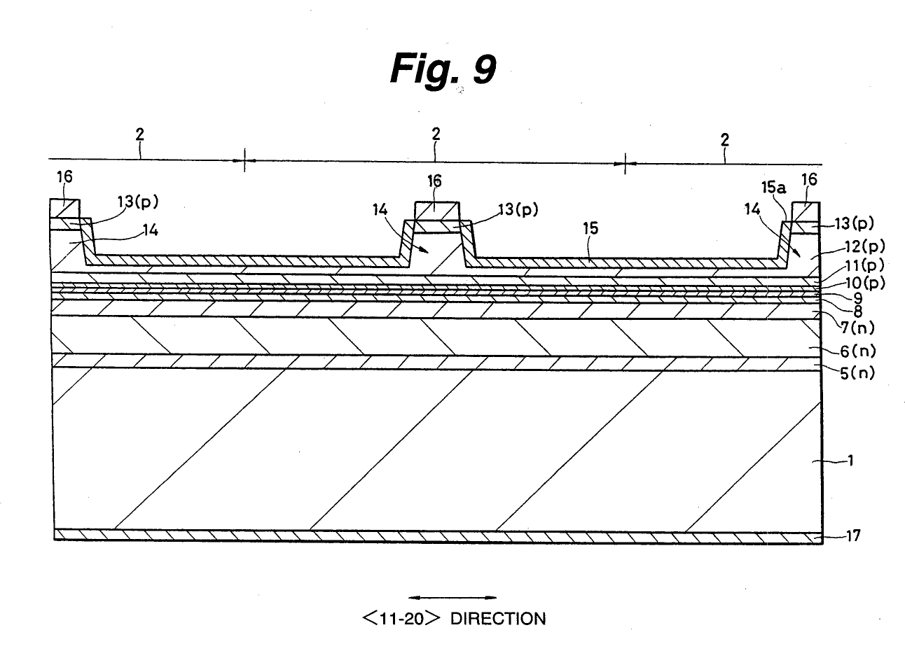

As shown in FIG. 8, the front surface of the GaN substrate 1 is cleaned by thermal cleaning or the like. Thereafter, an n-type GaN buffer layer 5, an n-type AlGaN clad layer 6, an n-type GaN optical waveguide layer 7, an undoped Ga₁₋ₓInₓN/Ga_{1-y}InN multiple quantum well structure active layer 8, an undoped InGaN deterioration protection layer 9, a p-type AlGaN cap layer 10, a p-type GaN optical waveguide layer 11, a p-type AlGaN clad layer 12, and a p-type GaN contact layer 13 are epitaxially grown on the front surface of the GaN substrate 1 by the MOCVD method.

The thickness of the n-type GaN buffer layer 5 is for example 0.05 μm. Si is doped as n-type impurities in the n-type GaN buffer layer 5. The thickness of the n-type AlGaN clad layer 6 is for example 1.0 μm. Si is doped as n-type impurities in the n-type AlGaN clad layer 6. The composition of Al of the n-type AlGaN clad layer 6 is for example 0.08. The thickness of the n-type GaN optical waveguide layer 7 is for example 0.1 μm. Si is doped as n-type impurities in the n-type GaN optical waveguide layer 7. The undoped Ga₁₋ₓInₓN/Ga_{1-y}In_{y}N multiple quantum well structure active layer 8 has an InₓGa₁₋ₓN layer as a well layer and an In_{y}Ga_{1-y}N layer as a barrier layer. The InₓGa₁₋ₓN layer has a thickness of 3.5 nm. x of InₓGa₁₋ₓN is 0.14. The In_{y}Ga_{1-y}N layer has a thickness of 7 nm. y of In_{y}Ga_{1-y}N is 0.02. The InyGa1−yN layer has three wells.

The undoped InGaN deterioration protection layer 9 has a grated structure of which the In composition gradually decreases from the plane that is in contact with the active layer 8 to the plane that is in contact with the undoped InGaN deterioration protection layer 9. The composition of In of the plane that is in contact with the active layer 8 accords with the composition y of In of the In_{y}Ga_{1-y}N layer as the barrier layer of the active layer 8. The composition of In of the plane that is in contact with the p-type AlGaN cap layer 10 is 0. The thickness of the undoped InGaN deterioration protection layer 9 is for example 20 nm.

The thickness of the p-type AlGaN cap layer 10 is for example 10 nm. For example, magnesium (Mg) is doped as p-type impurities in the p-type AlGaN cap layer 10. The composition of Al of the p-type AlGaN cap layer 10 is for example 0.2. The p-type AlGaN cap layer 10 prevents In from being removed from the active layer 8 when the p-type GaN optical waveguide layer 11, the p-type AlGaN clad layer 12, and the p-type contact layer 13 are grown. In addition, the p-type AlGaN cap layer 10 prevents carriers (electrons) from overflowing from the active layer 8. The thickness of the p-type GaN optical waveguide layer 11 is for example 0.1 μm. For example, Mg is doped as p-type impurities in the p-type GaN optical waveguide layer 11. The thickness of the p-type AlGaN clad layer 12 is for example 0.5 μm. For example, Mg is doped as p-type impurities in the p-type AlGaN clad layer 12. The composition of Al of the p-type AlGaN clad layer 12 is for example 0.08. The thickness of the p-type contact layer 13 is for example 0.1 μm. For example, Mg is doped as p-type impurities in the p-type contact layer 13.

The growing temperatures of the n-type GaN buffer layer 5, the n-type AlGaN clad layer 6, the n-type GaN optical waveguide layer 7, the p-type AlGaN cap layer 10, the p-type GaN optical waveguide layer 11, the p-type AlGaN clad layer 12, and the p-type contact layer 13, which do not contain In, are for example around 1000° C. The growing temperature of the Ga₁₋ₓInₓN/Ga_{1-y}In_{y}N multiple quantum well structure active layer 8, which includes In, is for example in the range from 700 to 800° C., preferably for example 730° C. The growing temperature at which the undoped InGaN deterioration protection layer 9 starts growing is set to for example 730° C., which is the same as the growing temperature of the active layer 8. Thereafter, the growing temperature is linearly raised. The growing temperature at which the undoped InGaN deterioration protection layer 9 ends growing is set to for example 835° C., which is the same as the growing temperature of the p-type AlGaN cap layer 10.

With respect to growing materials of the GaN type semiconductor layer, as a material of Ga, trimethyl gallium ((CH₃)₃Ga, TMG) is used; as a material of Al, trimethyl aluminum ((CH₃)₃Al, TMA) is used; as a material of In, trimethyl indium ((CH₃)₃In, TMI) is used; as a material of N, NH₃ is used. As a carrier gas, for example H₂ is used. With respect to dopants, as an n-type dopant, for example mono-silane is used. As a p-type dopant, for example bis (methylcyclopentyl) magnesium ((CH₃C₅H₄)₂Mg) or bis (cyclopentyl) magnesium ((C₅H₅)₂Mg) is used.

Thereafter, the GaN substrate 1 on which the GaN type semiconductor layer has been grown in the foregoing manner is removed from the MOCVD apparatus. Thereafter, an SiO₂ film (not shown) is fully formed for a thickness of for example 0.1 μm on the surface of the p-type contact layer 13 by the CVD method, vacuum evaporating method, spattering method or the like. Thereafter, a resist pattern (not shown) is formed in a predetermined shape in accordance with the shape of the ridge portion on the SiO₂ film by lithography. With a mask of the resist pattern, the SiO₂ film is etched by wet etching using for example hydrochloric acid type etching solution or RIE method using an etching gas containing fluorine for example CF₄ or CHF₃.

Next, with a mask of the SiO₂ film, the p-type AlGaN clad layer 12 is etched for a predetermined thickness. As a result, a ridge 14 that extends in a <1-100> direction is formed. The width of the ridge 14 is for example 3 μm. As an etching gas for the RIE, for example a chlorine type gas is used.

Thereafter, the SiO₂ film as the etching mask is removed. Thereafter, an insulation film 15 made of a SiO₂ film having a thickness of for example 0.3 μm is fully formed on the substrate by the CVD method, vacuum evaporating method, spattering method, or the like. The insulation film 15 serves to electrically insulate the substrate and protect the front surface thereof.

Thereafter, a resist pattern (not shown) that covers the front surface of the insulation film 15 excluding a p-type electrode forming region is formed by lithography.

Thereafter, with a mask of the resist pattern, the insulation film 15 is etched. As a result, an opening 15a is formed.

While the resist pattern is left, for example a Pd film, a Pt film, and an Au film are successively formed fully on the surface of the substrate by the vacuum evaporating method. Thereafter, the resist pattern is removed from the substrate along with the Pd film, the Pt film, and the Au film formed on the resist pattern (lift-off process). As a result, a p-type electrode 16 that is in contact with the p-type contact layer 13 is formed through the opening 15a of the insulation film 15. The thicknesses of the Pd film, the Pt film, and the Au film that compose the p-type electrode 16 are 10 nm, 100 nm, and 300 nm, respectively. Thereafter, an alloy process is performed for the substrate so as to ohmic-contact the p-side electrode 16 thereto.

Thereafter, for example a Ti film, a Pt film, and an Au film are successively formed on the rear surface of the GaN substrate 1 by for example vacuum evaporating method. As a result, an n-side electrode 17 having a Ti/Pt/Au structure is formed. The thicknesses of the Ti film, the Pt film, and the Au film that compose the n-side electrode 17 are for example 10 nm, 50 nm, and 100 nm, respectively. Thereafter, an alloy process is performed for the substrate so as to ohmic-contact the n-side electrode 17 thereto.

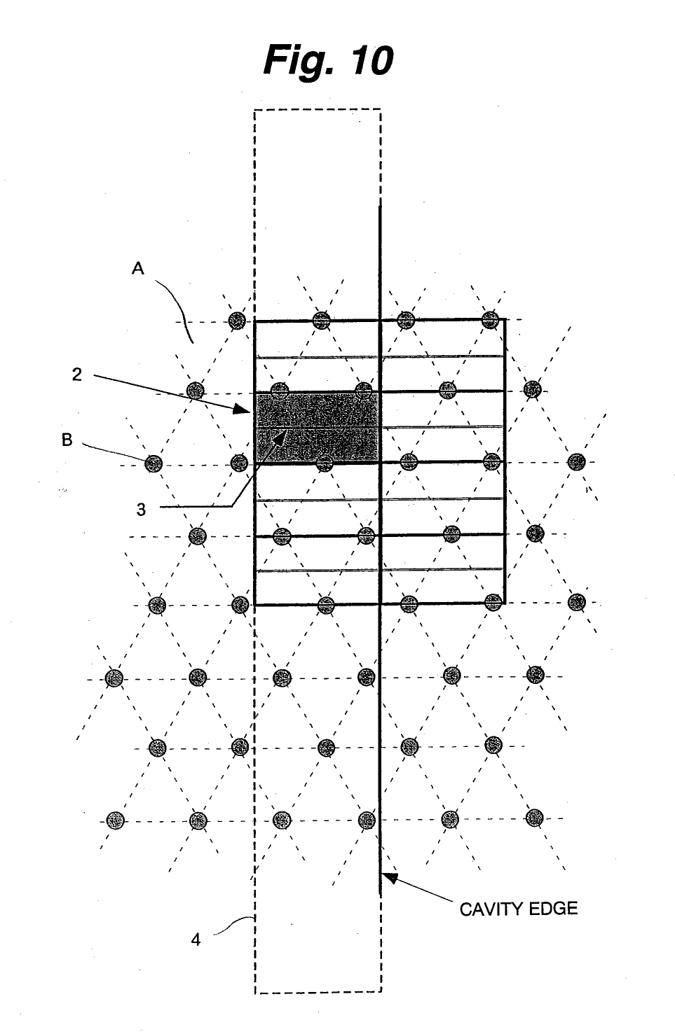

Thereafter, as shown in FIG. 10, the GaN substrate 1 on which the foregoing laser structure has been formed is scrubbed, for example, cleaved along the contour lines of a device region 2 (one section surrounded by thick lines). As a result, a laser bar 4 having end planes of a resonator is formed. The end planes of the resonator are coated. Thereafter, the laser bar 4 is scrubbed, for example, cleaved so as to obtain a chip is obtained.

In FIG. 10, one gray rectangle represents a GaN type semiconductor laser. A straight line drawn near the center of the gray rectangle represents a laser stripe 3. The laser stripe 3 accords with a position of a light emitting region. In addition, a rectangle illustrated by broken lines represents the laser bar 4. Longer sides of the laser bar 4 accord with the end planes of the resonator.

In the example shown in FIG. 10, the size of the GaN type semiconductor laser is for example 600 μm×346 μm. The substrate is scrubbed in the lateral direction (longer side direction) along a straight line that connects the regions B and in the lengthwise direction (shorter side direction) along a straight line that does not pass through the regions B. As a result, a GaN type semiconductor laser of the size is separated from the substrate.

In this case, since the regions B exist on the end planes of the longer sides of each GaN type semiconductor laser, when a device is designed so that the laser stripe 3 is positioned near a straight line that connects the center points of the shorter sides of the laser stripe 3, the light emitting region can be prevented from being affected by the regions B.

By scrubbing, for example, cleaving the substrate along the straight line in the lengthwise direction shown in FIG. 10, mirrors of the resonator are formed on the end planes. Since the straight line does not pass through the regions B, the mirrors are not adversely affected by dislocations of the regions B. Thus, a GaN type semiconductor laser having good light emitting characteristics and good reliability can be obtained.

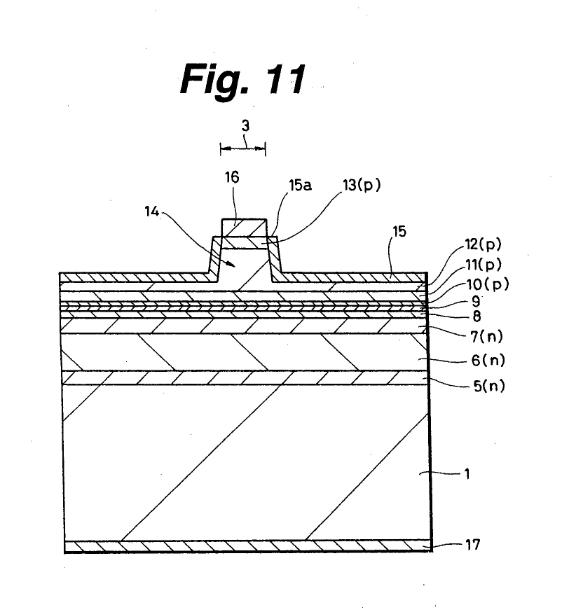

Thus, as shown in FIG. 11, a GaN type semiconductor laser having desired ridge structure and SCH structure is produced.

As described above, according to the first embodiment of the present invention, in the GaN substrate 1 of which the regions B having a high average dislocation density are periodically arranged in a hexagonal lattice shape in the region A having a low average dislocation density, the upper portions of the regions B are etched out so that the front surfaces of the regions B are spaced apart from the principal plane of the GaN substrate 1. In addition, a GaN type semiconductor layer that forms a laser structure is grown on the GaN substrate 1. As a result, the GaN type semiconductor layer that forms the laser structure can be prevented from being adversely affected by the regions B. Thus, a GaN type semiconductor laser that has good light emitting characteristics, good reliability, and long life can be accomplished.

In addition, according to the first embodiment, the undoped InGaN deterioration protection layer 9 is disposed adjacent to the active layer 8. In addition, the p-type AlGaN cap layer 10 is disposed adjacent to the undoped InGaN deterioration protection layer 9. Thus, the undoped InGaN deterioration protection layer 9 can remarkably suppress a stress of the active layer 8 by the p-type AlGaN cap layer 10. In addition, the undoped InGaN deterioration protection layer 9 can effectively prevent Mg as a p-type dopant of a p-type layer from diffusing in the active layer 7.

### Second Embodiment

Next, a second embodiment of the present invention will be described.

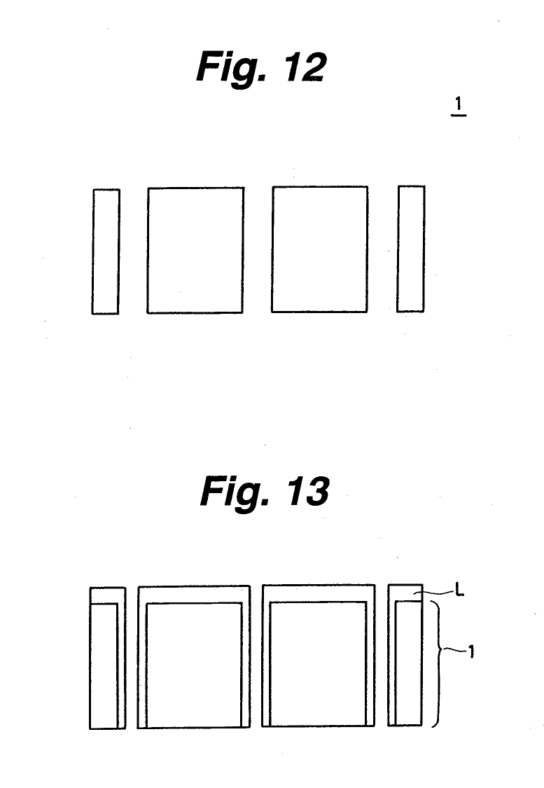

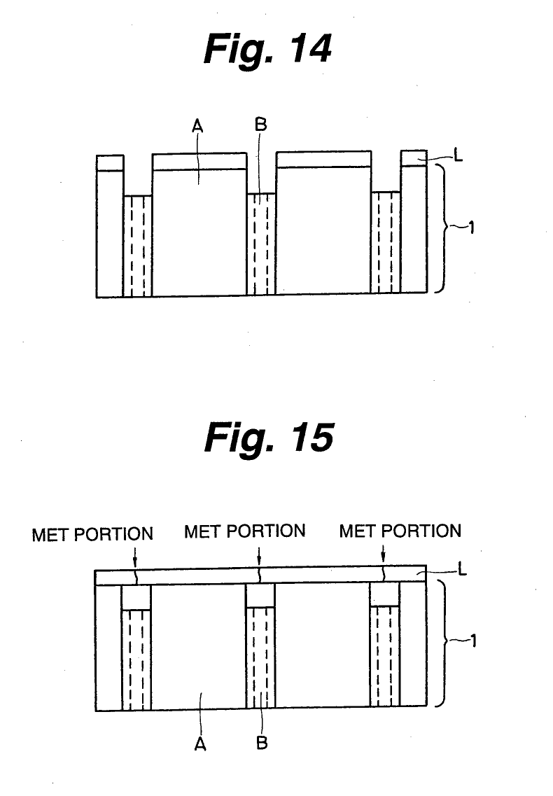

As shown in FIG. 12, according to the second embodiment, all regions B of a GaN substrate 1 are etched out so that the etched-out portions become holes. Thereafter, as shown in FIG. 13, a GaN type semiconductor layer L is grown on the GaN substrate 1 by the MOCVD method or the like.

Except for the foregoing portion, the second embodiment is the same as the first embodiment. Thus, the description of the other portions of the second embodiment is omitted.

According to the second embodiment, the same advantage as the first embodiment can be obtained.

### Third Embodiment

Next, a third embodiment of the present invention will be described.

As shown in FIG. 14, according to the third embodiment, upper portions of regions B of a GaN substrate 1 are etched out as with the first embodiment. In this case, dry-etching such as RIE is performed. Thereafter, since the crystallinity of the regions B is worse than that of the region A, a GaN type semiconductor layer L is grown in the region A, not the regions B, by the MOCVD method or the like. As a result, the GaN type semiconductor layer L can be grown on the main plane, namely, the region A, of the GaN substrate 1.

Except for the foregoing portion, the third embodiment is the same as the first embodiment. Thus, the description of the other portions of the third embodiment is omitted.

According to the third embodiment, the same advantage as the first embodiment can be obtained.

### Fourth Embodiment

Next, a fourth embodiment of the present invention will be described.

As shown in FIG. 15, according to the fourth embodiment of the present invention, upper portions of regions B of a GaN substrate 1 are etched out as with the first embodiment. Thereafter, since the crystallinity of the regions B is worse than that of the region A, a GaN type semiconductor layer L is laterally grown on the region A, not the regions B. As a result, the GaN type semiconductor layer L is grown on the principal plane, namely, laterally grown from the region A and met above the regions B. As a result, the front surface of the GaN type semiconductor layer L can be smoothened. Alternatively, the GaN type semiconductor layer L may not be met and smoothened.

Except for the foregoing portion, the fourth embodiment is the same as the first embodiment. Thus, the description of the other portions of the fourth embodiment is omitted.

According to the fourth embodiment, the same advantage as the first embodiment can be obtained.

### Fifth Embodiment

Next, a fifth embodiment of the present invention will be described.

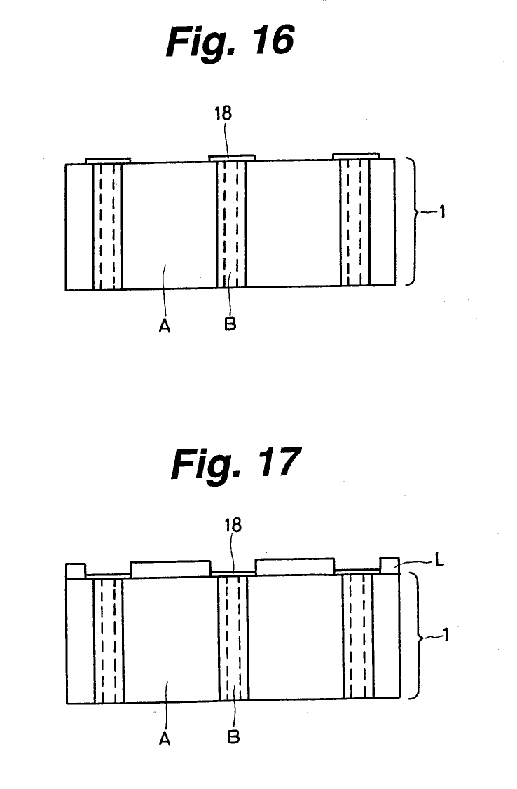

As shown in FIG. 16, according to the fifth embodiment, an insulation film 18 such as an SiO₂ film is formed so that it fully coats regions B of the principal plane of a GaN substrate 1. As long as the insulation film 18 fully coats the regions B, the shape of the insulation film 18 is not restricted. The insulation film 18 may be formed in a circular shape in accordance with the shape of the region B. Alternatively, the insulation film 18 may be formed in a square shape or another polygon shape that contains the region B. Alternatively, the insulation film 18 may be formed in a stripe shape that fully coats a sequence of regions B and a region A formed therebetween. Thereafter, as shown in FIG. 17, a GaN type semiconductor layer L is grown on the GaN substrate 1 by the MOCVD method or the like. At that point, since the insulation film 18 functions as a growing mask, the GaN type semiconductor layer L is grown on only a portion of which the GaN type semiconductor layer L is not coated by the insulation film 18 on the principal plane of the GaN substrate 1.

Except for the foregoing portion, the fifth embodiment is the same as the first embodiment. Thus, the description of the other portions of the fifth embodiment is omitted.

According to the fifth embodiment of the present invention, the same advantage as the first embodiment can be obtained.

### Sixth Embodiment

Next, a sixth embodiment of the present invention will be described.

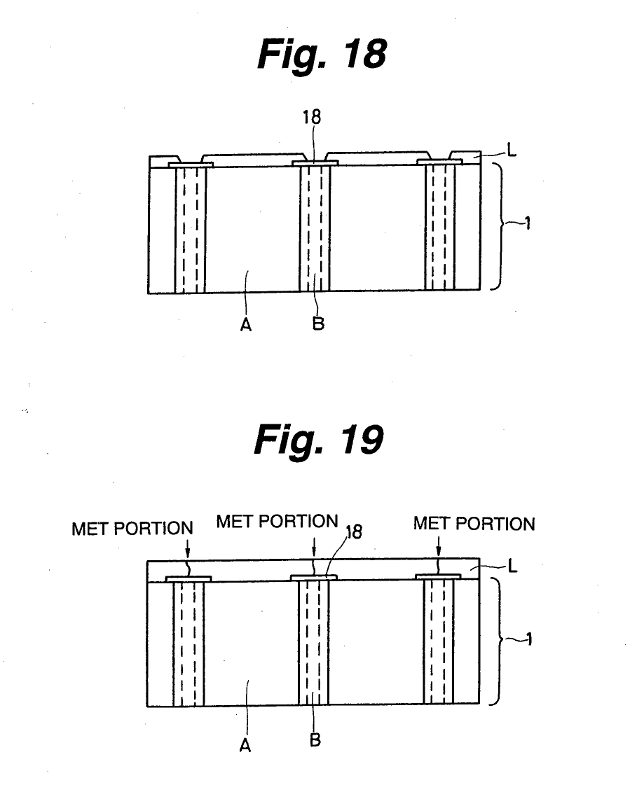

As shown in FIG. 18, according to the sixth embodiment, an insulation film 18 such as a SiO₂ film is formed so that it fully coats regions B on the principal plane of a GaN substrate 1 as with the fifth embodiment. Thereafter, steps shown in FIG. 18 and FIG. 19 are performed. Thereafter, a GaN type semiconductor layer L is laterally grown on the GaN substrate 1 by the ELO method using for example the MOCVD method. At that point, the GaN type semiconductor layer L that is laterally grown on the insulation film 18 is met on the insulation film 18. Alternatively, the GaN type semiconductor layer L may not be met on the insulation film 18.

Except for the foregoing portion, the sixth embodiment is the same as the first embodiment. Thus, the description of the other portions of the sixth embodiment is omitted.

According to the sixth embodiment, the same advantage as the first embodiment can be obtained.

### Seventh Embodiment

Next, a seventh embodiment of the present invention will be described.

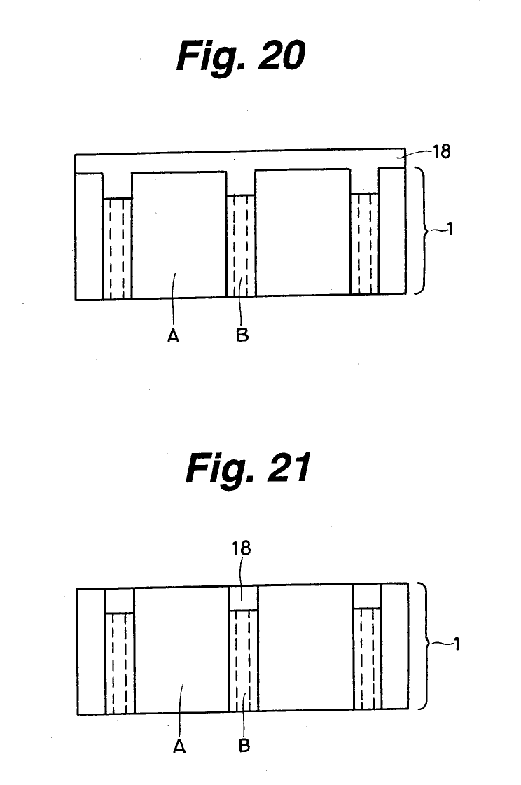

As shown in FIG. 20, according to the seventh embodiment, upper portions of regions B of a GaN substrate 1 are etched out as with the first embodiment. Thereafter, an insulation film 18 such as a SiO₂ film is fully formed on the surface of the GaN substrate 1 so as to fill the etched-out portions of the regions B with the insulation film 18. Thereafter, as shown in FIG. 21, the insulation film 18 is etched back by for example the RIE method so as to leave the insulation film 18 in the etched-out portions of the regions B. Thereafter, as with the fifth embodiment or sixth embodiment, the GaN type semiconductor layer L is grown on the GaN substrate 1.

Except for the foregoing portion, the seventh embodiment is the same as the first embodiment. Thus, the description of the other portions of the seventh embodiment is omitted.

According to the seventh embodiment, the same advantage as the first embodiment can be obtained.

### Eighth Embodiment

Next, an eighth embodiment of the present invention will be described.

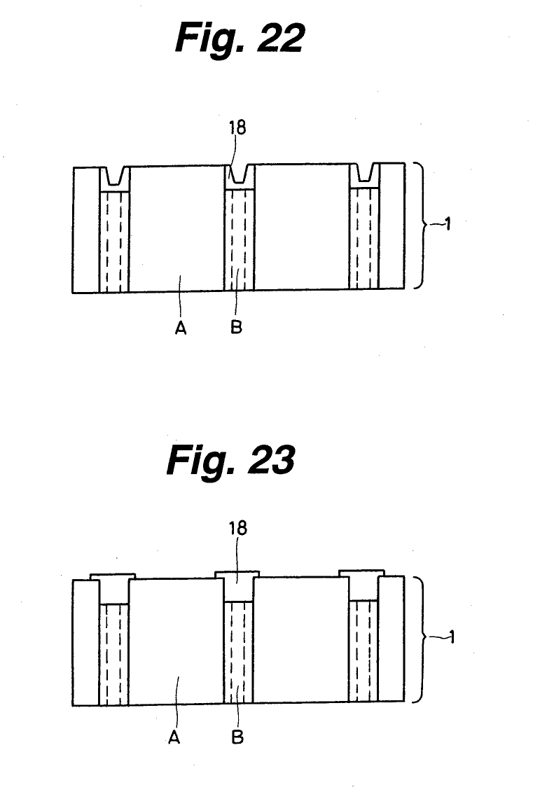

As shown in FIG. 22, according to the eight embodiment, upper portions of regions B of a GaN substrate 1 are etched out as with the first embodiment. Thereafter, an insulation film 18 such as a SiO₂ film is fully formed on the GaN substrate 1. At that point, the insulation film 18 has a thickness for which the etched-out portions of the regions B are not fully filled with the insulation film 18. Thereafter, the insulation film 18 is etched back by for example the RIE method so as to remove the insulation film 18 from the region A. Thereafter, a GaN type semiconductor layer L is grown on the GaN substrate 1 as with the fifth or sixth embodiment.

Except for the foregoing portion, the eighth embodiment is the same as the first embodiment. Thus, the description of the other portions of the eighth embodiment is omitted.

According to the eighth embodiment, the same advantage as the first embodiment can be obtained.

### Ninth Embodiment

Next, a ninth embodiment of the present invention will be described.

As shown in FIG. 23, according to the ninth embodiment, upper portions of regions B of a GaN substrate 1 are etched out as with the first embodiment. Thereafter, an insulation film 18 such as a SiO₂ film is fully formed on the surface of the GaN substrate 1 so as to fill the etched-out portions with the insulation film 18. Thereafter, the insulation film 18 is etched so that it is patterned in the same shape as the fifth embodiment. Thereafter, a GaN type semiconductor layer L is formed on the GaN substrate 1 as with the fifth embodiment or sixth embodiment.

Except for the foregoing portion, the ninth embodiment is the same as the first embodiment. Thus, the description of the other portions of the ninth embodiment is omitted.

According to the ninth embodiment, the same advantage as the first embodiment can be obtained.

### Tenth Embodiment

Next, a tenth embodiment of the present invention will be described.

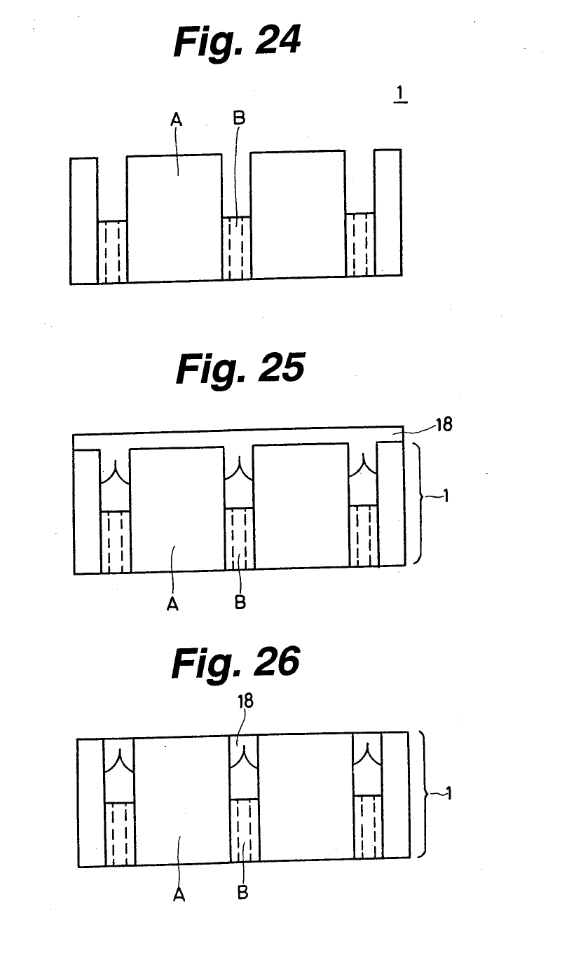

As shown in FIG. 24, according to the tenth embodiment, upper portions of regions B of a GaN substrate 1 are etched out as with the first embodiment. In this case, the etched-out depth is as large as for example several ten μm. Thereafter, as shown in FIG. 25, an insulation film 18 such as a SiO₂ film is fully formed on the surface of the GaN substrate 1. At that point, since the etched-out portions of the regions B are deep, they are not fully filled with the insulation film 18. As a result, the GaN substrate 1 has holes. Thereafter, the insulation film 18 is etched back by for example the RIE method so as to remove the insulation film 18 from the region A. Thereafter, a GaN type semiconductor layer L is grown on the GaN substrate 1 as with the fifth or sixth embodiment.

Except for the foregoing portion, the tenth embodiment is the same as the first embodiment. Thus, the description of the other portions of the tenth embodiment is omitted.

According to the tenth embodiment, the same advantage as the first embodiment can be obtained.

### Eleventh Embodiment

Next, an eleventh embodiment of the present invention will be described.

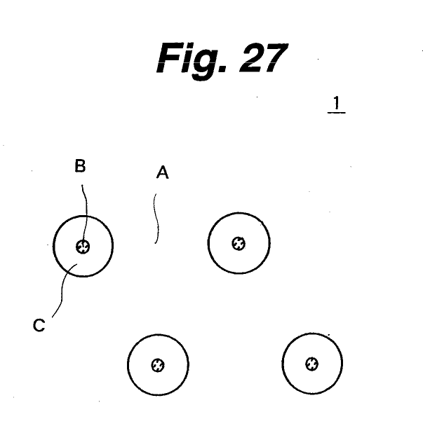

As shown in FIG. 27, according to the eleventh embodiment, regions B are periodically arranged in a hexagonal lattice shape in an area A of a GaN substrate 1 as with the first embodiment. However, regions C are formed as transitional regions between the region A and the regions B unlike with the first embodiment. The average dislocation density of the regions C is in the middle of the average dislocation density of the region A and the average dislocation density of the regions B. In reality, the average dislocation density of the region A is 2×10⁶ cm⁻² or lower. The average dislocation density of the regions B is 1×10⁸ cm⁻² or greater. The average dislocation density of the regions C is smaller than 1×10⁸ cm⁻² and greater than 2×10⁶ cm⁻², for example around (1 to 2)×10⁷ cm⁻². The arrangement period of the regions B (the distance between the centers of the most adjacent regions B) is for example 300 μl. The diameter of each region B is for example 20 μm. The diameter of each region C is for example 120 μm.

Unlike with the first embodiment of which the upper portions of the regions B of the GaN substrate 1 are etched out, according to the eleventh embodiment, the upper portions of both the regions B and the regions C of the GaN substrate 1 are etched out.

Except for the foregoing portion, the eleventh embodiment is the same as the first embodiment. Thus, the description of the other portions of the eleventh embodiment is omitted.

According to the eleventh embodiment, the same advantage as the first embodiment can be obtained.

### Twelfth Embodiment

Next, a twelfth embodiment of the present invention will be described.

Unlike with the second embodiment of which all the regions B of the GaN substrate 1 are etched out, according to the twelfth embodiment, all regions B and regions C of a GaN substrate 1 are etched out.

Except for the foregoing portion, the twelfth embodiment is the same as the first embodiment. Thus, the description of the other portions of the twelfth embodiment is omitted.

According to the twelfth embodiment, the same advantage as the first embodiment can be obtained.

### Thirteenth Embodiment

Next, a thirteenth embodiment of the present invention will be described.

Unlike with the third embodiment of which the upper portions of the regions B of the GaN substrate 1 are etched out, according to the thirteenth embodiment, upper portions of both regions B and regions C of a GaN substrate 1 are etched out.

Except for the foregoing portion, the thirteen embodiment is the same as the first embodiment and the eleventh embodiment. Thus, the description of the other portions of the thirteenth embodiment is omitted.

According to the thirteenth embodiment, the same advantage as the first embodiment can be obtained.

### Fourteenth Embodiment

Next, a fourteenth embodiment of the present invention will be described.

Unlike with the fourth embodiment of which the upper portions of the regions B of the GaN substrate 1 are etched out, according to the fourteenth embodiment, upper portions of both regions B and regions C of a GaN substrate 1 are etched out.

Except for the foregoing portion, the fourteenth embodiment is the same as the first embodiment and the eleventh embodiment. Thus, the description of the other portions of the fourteenth embodiment is omitted.

According to the fourteenth embodiment, the same advantage as the first embodiment can be obtained.

### Fifteenth Embodiment

Next, a fifteenth embodiment of the present invention will be described.

Unlike with the fifth embodiment of which the regions B of the GaN substrate 1 are coated with the insulation film 18, according to the fifteenth embodiment, regions B and regions C of a GaN substrate 1 are coated with an insulation film 18.

Except for the foregoing portion, the fifteenth embodiment is the same as the first embodiment, the fifth embodiment, and the eleventh embodiment. Thus, the description of the other portions of the fifteenth embodiment is omitted.

According to the fifteenth embodiment, the same advantage as the first embodiment can be obtained.

### Sixteenth Embodiment

Next, a sixteenth embodiment of the present invention will be described.

Unlike with the sixth embodiment of which the regions B of the GaN substrate 1 are coated with the insulation film 18, according to the sixteenth embodiment, both regions B and regions C of a GaN substrate 1 are coated with an insulation film 18.

Except for the foregoing portion, the sixteenth embodiment is the same as the first embodiment, the fifth embodiment, and the eleventh embodiment. Thus, the description of the other portions of the sixteenth embodiment is omitted.

According to the sixteenth embodiment, the same advantage as the first embodiment can be obtained.

### Seventeenth Embodiment

Next, a seventeenth embodiment of the present invention will be described.

Unlike with the seventh embodiment of which the upper portions of the regions B of the GaN substrate 1 are etched out, according to the seventeenth embodiment, upper portions of regions B and regions C of a GaN substrate 1 are etched out.

Except for the foregoing portion, the seventeenth embodiment is the same as the first embodiment, the fifth embodiment, and the eleventh embodiment. Thus, the description of the other portions of the seventeenth embodiment is omitted.

According to the seventeenth embodiment, the same advantage as the first embodiment can be obtained.

### Eighteenth Embodiment

Next, an eighteenth embodiment of the present invention will be described.

Unlike with the eighth embodiment of which the upper portions of the regions B of the GaN substrate 1 are etched out, according to the eighteenth embodiment, upper portions of both regions B and regions C of a GaN substrate 1 are etched out.

Except for the foregoing portion, the eighteenth embodiment is the same as the first embodiment, the fifth embodiment, and the eleventh embodiment. Thus, the description of the other portions of the eighteenth embodiment is omitted.

According to the eighteen embodiment, the same advantage as the first embodiment can be obtained.

### Nineteenth Embodiment

Next, a nineteenth embodiment of the present invention will be described.

Unlike with the ninth embodiment of which the upper portions of the regions B of the GaN substrate 1 are etched out, according to the nineteenth embodiment, upper portions of both regions B and regions C of the GaN substrate 1 are etched out.

Except for the foregoing portion, the nineteenth embodiment is the same as the first embodiment, the fifth embodiment, and the eleventh embodiment. Thus, the description of the other portions of the nineteenth embodiment is omitted.

According to the nineteenth embodiment, the same advantage as the first embodiment can be obtained.

### Twentieth Embodiment

Next, a twentieth embodiment of the present invention will be described.

Unlike with the tenth embodiment of which the upper portions of the regions B of the GaN substrate 1 are etched out, according to the twentieth embodiment, upper portions of regions B and regions C of a GaN substrate 1 are etched out.

Except for the foregoing portion, the twentieth embodiment is the same as the first embodiment, the fifth embodiment, and the eleventh embodiment. Thus, the description of the other portions of the twentieth embodiment is omitted.

According to the twentieth embodiment, the same advantage as the first embodiment can be obtained.

### Twenty First Embodiment

Next, a twenty first embodiment of the present invention will be described.

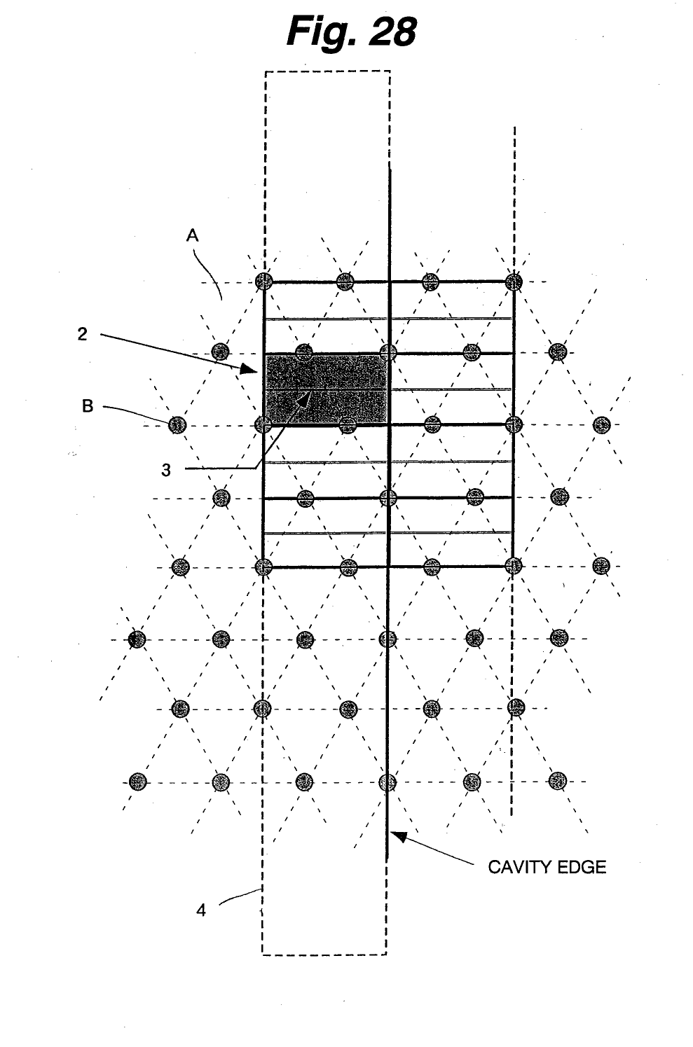

As shown in FIG. 28, according to the twenty first embodiment, contour lines of longer sides and shorter sides of a rectangular device region 2 are straight lines that connect centers of regions B unlike with the first embodiment. In this case, a laser stripe 3 is positioned on a straight line that connects the centers of the short sides of the device region 2. As a result, a light emitting region can be prevented from being adversely affected by the regions B.

Unlike with the first embodiment, according to the twenty first embodiment, the device region 2 is scrubbed by cleaving along the contour lines that connect the centers of the regions B. As a result, a mirror of a resonator is formed.

Since there are many dislocations in the regions B, it is thought that the regions B are more easily broken than the region A. Thus, when the device region 2 is scrubbed along straight lines that connect the regions B, since they function as perforations, the region can be neatly cleaved. At that point, since there are many dislocations on end planes of the regions B, although the end planes thereof do not always become flat, the end planes of the region A become flat.

The end planes of the laser stripe 3 should be flat. However, in the arrangement shown in FIG. 28, the end planes of the regions B do not adversely affect the light emitting characteristics and so forth.

Except for the foregoing portion, the twenty first embodiment is the same as the first embodiment. Thus, the description of the other portions of the twenty first embodiment is omitted.

According to the twenty first embodiment, the same advantage as the first embodiment can be obtained.

### Twenty Second Embodiment

Next, a twenty second embodiment of the present invention will be described.

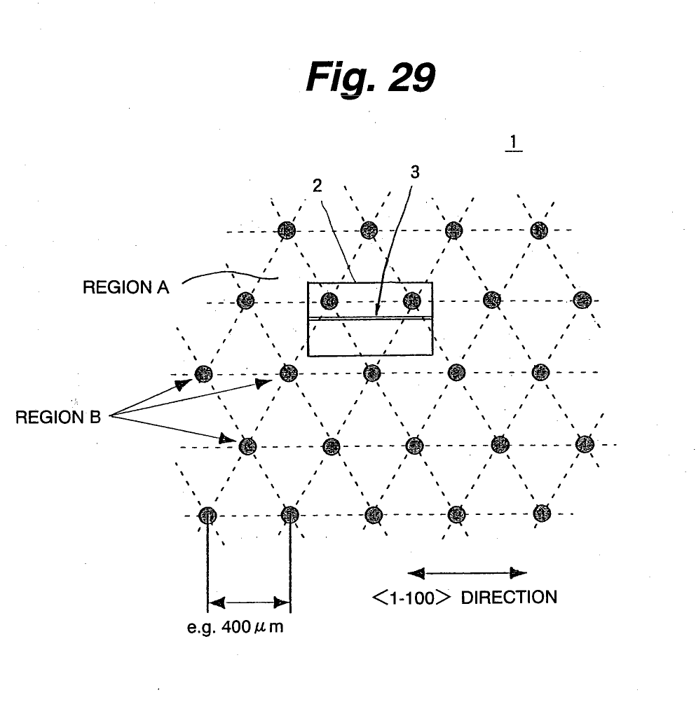

FIG. 29 is a plan view showing a GaN substrate according to the twenty second embodiment. As shown in FIG. 29, according to the twenty second embodiment, a device region 2 is confined so that regions B are not contained in a laser stripe 3. The laser stripe 3 is spaced apart from each region B by 50 μm or greater. In this case, the device region 2 contains two regions B.

Except for the foregoing portion, the twenty second embodiment is the same as the first embodiment. Thus, the description of the other portions of the twenty second embodiment is omitted.

According to the twenty second embodiment, the same advantage as the first embodiment can be obtained.

### Twenty Third Embodiment

Next, a twenty third embodiment of the present invention will be described.

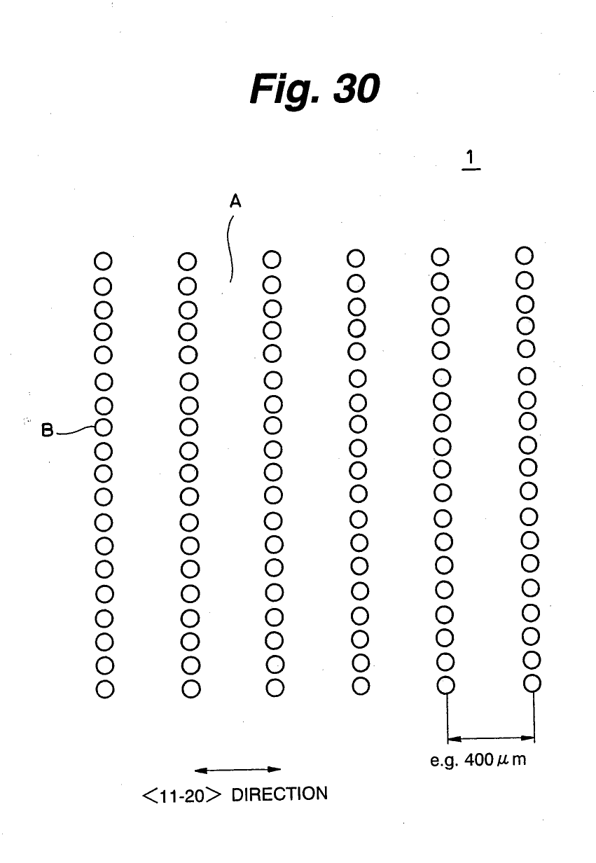

FIG. 30 is a plan view showing a GaN substrate according to the twenty third embodiment. The GaN substrate 1 is an n-type semiconductor and has a C plane orientation. Alternatively, the GaN substrate 1 may have an R plane orientation, an A plane orientation, or an M plane orientation. In the GaN substrate 1, regions B made of a crystal having a high average dislocation density are periodically arranged in a <11-20> direction of GaN at an interval of for example 400 μm and at an interval of for example 20 to 100 μm in a <1-100> direction that is perpendicular to the <11-20> direction in a region A made of a crystal having a low average dislocation density. Alternatively, the <11-20> direction may be substituted for the direction <1-100>.

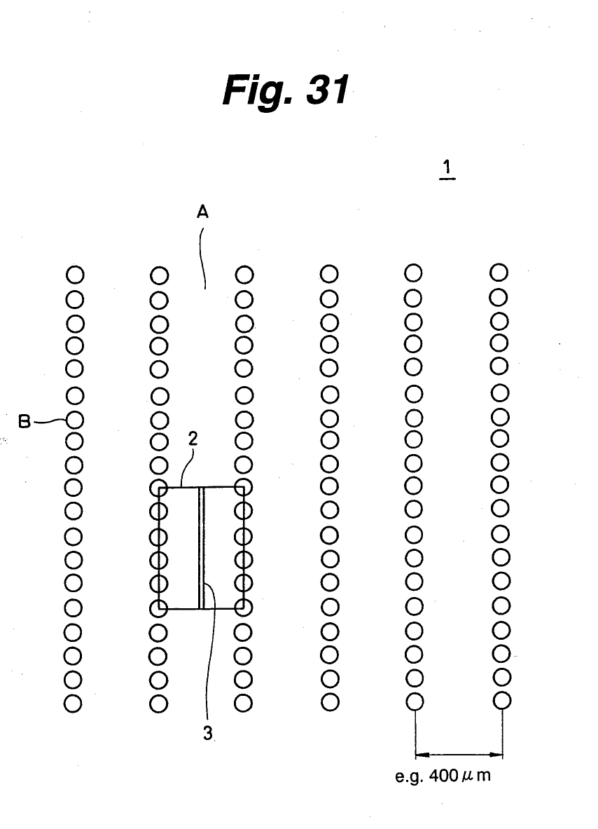

According to the twenty third embodiment, as shown in FIG. 31, a device region 2 is confined so that a pair of end planes that are in parallel with a laser stripe 3 pass through a row of regions B in the <1-100> direction and that a laser stripe 3 is positioned near the center of a region between two rows of the regions B. In this case, the device region 2 does not substantially contain rows of the regions B.

Except for the foregoing portion, the twenty third embodiment is the same as the first embodiment. Thus, the description of the other portions of the twenty third embodiment is omitted.

According to the twenty third embodiment, the same advantage as the first embodiment can be obtained.

### Twenty Fourth Embodiment

Next, a twenty fourth embodiment of the present invention will be described.

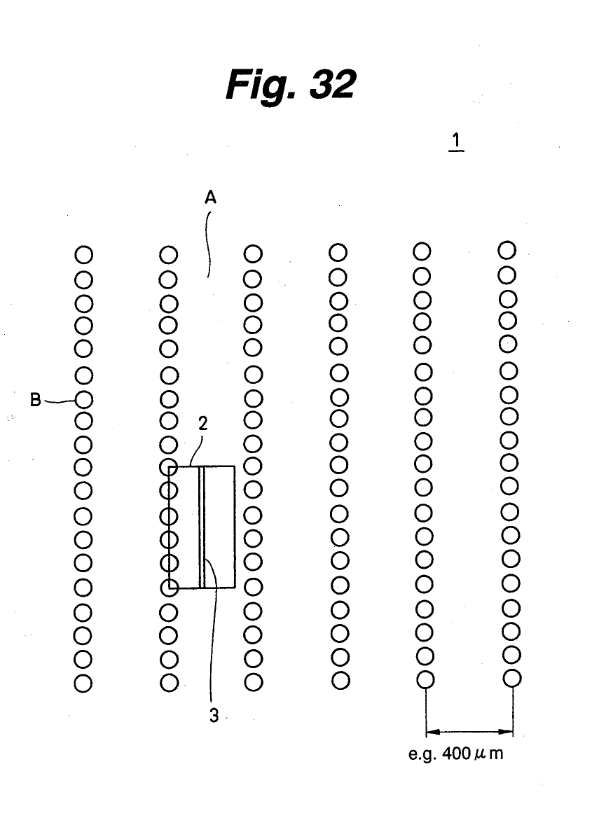

As shown in FIG. 32, according to the twenty fourth embodiment, a GaN substrate 1 that is the same as the twenty third embodiment is used. However, unlike with the twenty third embodiment, one end plane that is in parallel with a laser stripe 3 passes through a row of regions B in a <1-100> direction. Another end plane passes through a position that is apart from a row of the regions B. In this case, a device region 2 does not substantially contain a row of the regions B.

Except for the foregoing portion, the twenty fourth embodiment is the same as the twenty third embodiment and the first embodiment. Thus, the description of the other portions of the twenty fourth embodiment is omitted.

According to the twenty fourth embodiment, the same advantage as the first embodiment can be obtained.

### Twenty Fifth Embodiment

Next, a twenty fifth embodiment of the present invention will be described.

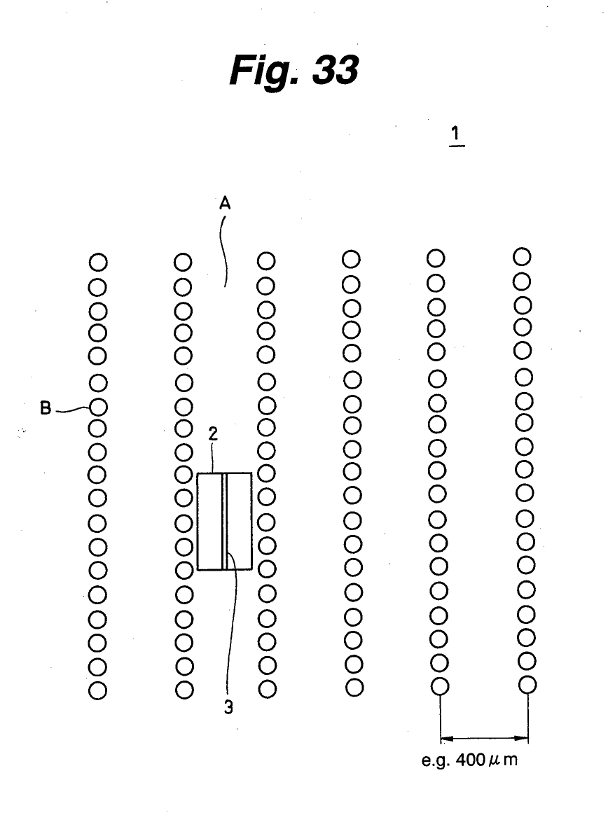

As shown in FIG. 33, according to the twenty fifth embodiment, a GaN substrate 1 that is the same as the twenty third embodiment is used. However, unlike with the twenty third embodiment, according to the twenty fifth embodiment, a device region 2 is confined so that a pair of end planes of a laser stripe 3 are positioned between two rows of regions B in a <1-100> direction and that a laser stripe 3 is positioned near the center of a region between the two rows of the regions B. In this case, the device region 2 does not substantially contain the rows of the regions B.

Except for the foregoing portion, the twenty fifth embodiment is the same as the twenty third embodiment and the first embodiment. Thus, the description of the other portions of the twenty fifth embodiment is omitted.

According to the twenty fifth embodiment, the same advantage as the first embodiment can be obtained.

### Twenty Sixth Embodiment

Next, a twenty sixth embodiment of the present invention will be described.

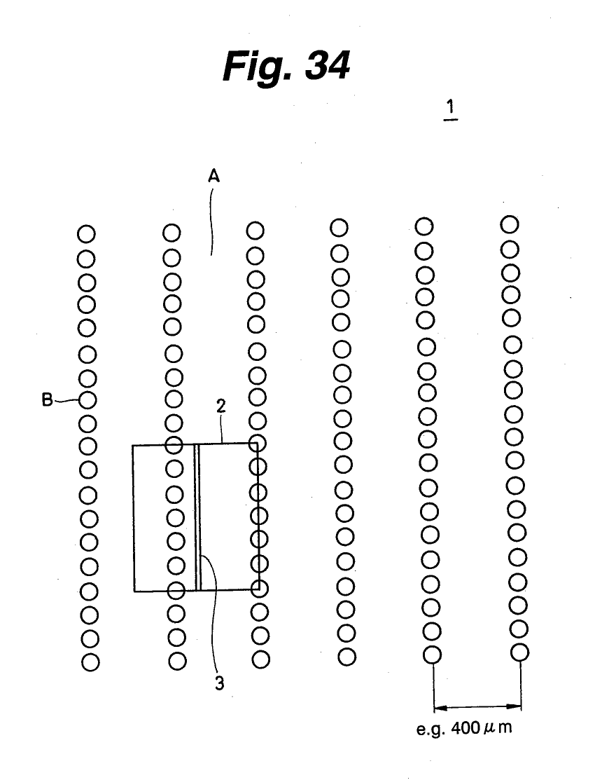

As shown in FIG. 34, according to the twenty sixth embodiment, a GaN substrate 1 that is the same as the twenty third embodiment is used. However, unlike with the twenty third embodiment, one end plane that is in parallel with a laser stripe 3 passes through a row of regions B in a <1-100> direction and that another end plane is positioned between the adjacent two rows of regions B and that a laser stripe 3 passes through a position spaced apart from the row of regions B through which the one end plane passes by 50 μm or greater. In this case, the device region 2 contains one row of regions B.

Except for the foregoing portion, the twenty sixth embodiment is the same as the twenty third embodiment and the first embodiment. Thus, the description of the other portions of the twenty sixth embodiment is omitted.

According to the twenty sixth embodiment, the same advantage as the first embodiment can be obtained.

### Twenty Seventh Embodiment

Next, a twenty seventh embodiment of the present invention will be described.

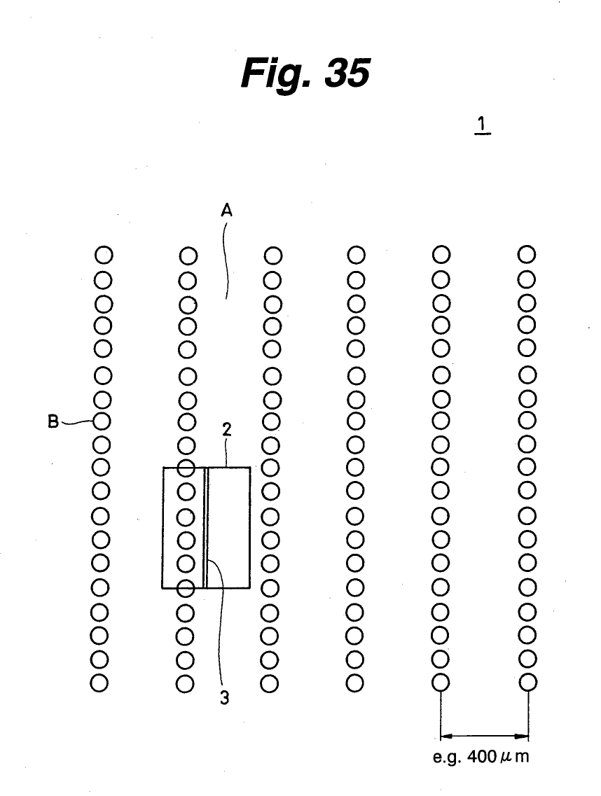

As shown in FIG. 35, according to the twenty seventh embodiment, a GaN substrate 1 that is the same as the twenty third embodiment is used. However, unlike with the twenty third embodiment, one end plane that is in parallel with a laser stripe 3 passes through a position that is apart from a row of regions B in a <1-100> direction. Another end plane passes through a position between the adjacent two rows of regions B. A laser stripe 3 passes through a position spaced apart from the row of regions B by 50 μm or greater. In this case, a device region 2 contains one row of regions B.

Except for the foregoing portion, the twenty seventh embodiment is the same as the twenty third embodiment and the first embodiment. Thus, the description of the other portions of the twenty seventh embodiment is omitted.

According to the twenty seventh embodiment, the same advantage as the first embodiment can be obtained.

### Twenty Eighth Embodiment

Next, a twenty eighth embodiment of the present invention will be described.

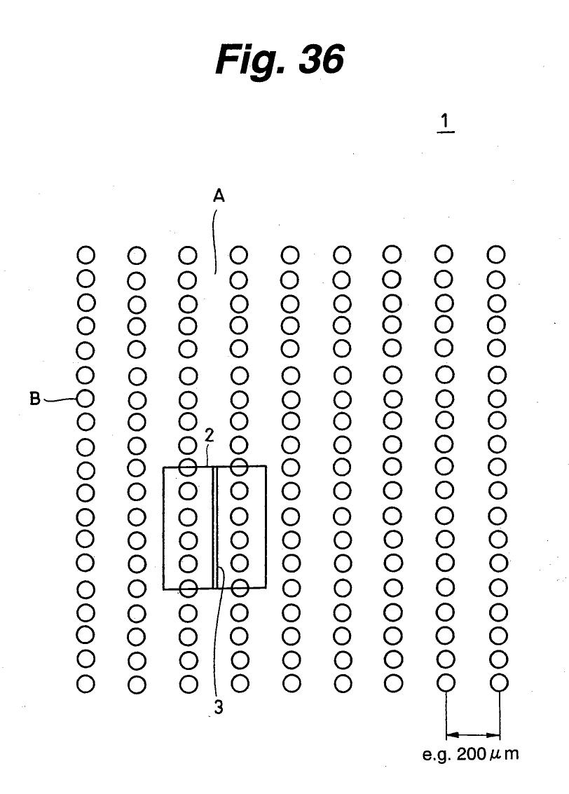

FIG. 36 is a plan view showing a GaN substrate 1 according to the twenty eighth embodiment. The GaN substrate 1 according to the twenty eighth embodiment is the same as the tenth embodiment except that regions B are periodically arranged at an interval of for example 200 μm in a <11-20> orientation of GaN. In this case, a device region 2 contains two rows of regions B.

As shown in FIG. 36, according to the twenty eighth embodiment, a laser stripe 3 is positioned near the center of adjacent rows of regions B. A pair of end planes that are in parallel with the laser stripe 3 are positioned near the centers of regions between two adjacent rows of regions B on the right and left of the laser stripe 3.

Except for the foregoing portion, the twenty eighth embodiment is the same as the twenty third embodiment and the first embodiment. Thus, the description of the other portions of the twenty eighth embodiment is omitted.

According to the twenty eighth embodiment, the same advantage as the first embodiment can be obtained.

### Twenty Ninth Embodiment

Next, a twenty ninth embodiment of the present invention will be described.

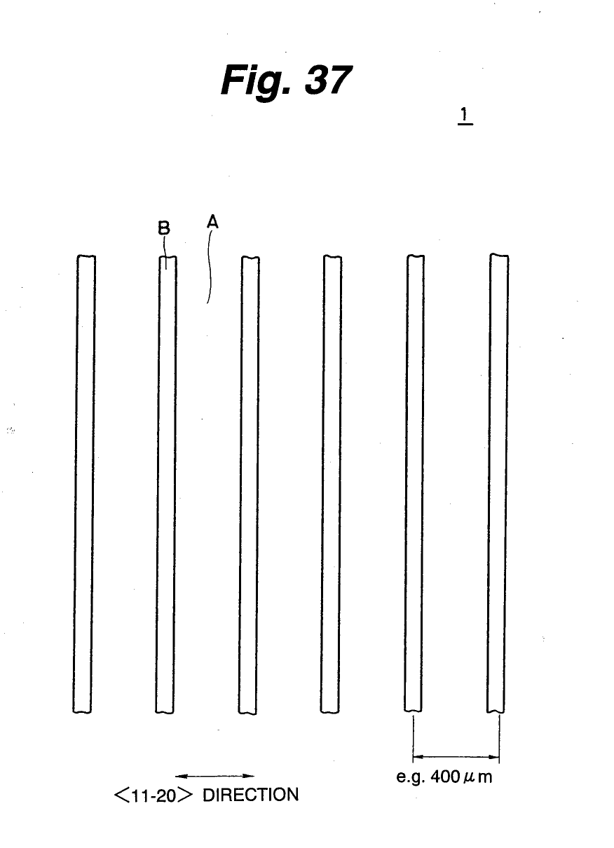

FIG. 37 is a plan view showing a GaN substrate according to the twenty ninth embodiment. The GaN substrate 1 is an n-type semiconductor and has a C plane orientation. Alternatively, the GaN substrate 1 may have an R plane orientation, an A plane orientation, or an M plane orientation. In the GaN substrate 1, regions B that are made of a crystal having a high average dislocation density and that linearly extend in a <1-100> direction of GaN are periodically arranged at an interval of for example 400 μm in a <11-20> orientation perpendicular to the <1-100> direction. Alternatively, the <1-100> direction may be substituted for the <11-20> orientation.

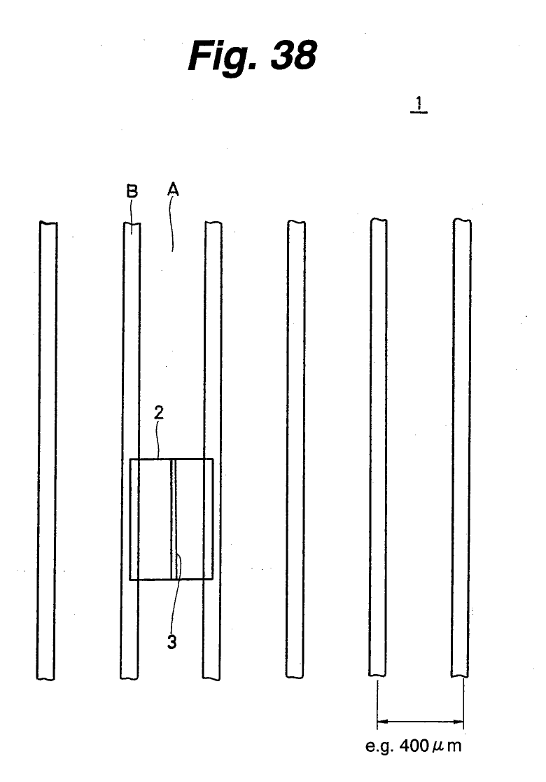

According to the twenty ninth embodiment, as shown in FIG. 38, a device region 2 is confined so that a pair of end planes that are in parallel with a laser stripe 3 pass through regions B and that the laser stripe 3 is positioned near the center of a region between the regions B. In this case, the device region 2 does not substantially contain regions B.

Except for the foregoing portion, the twenty ninth embodiment is the same as the first embodiment. Thus, the description of the other portions of the twenty ninth embodiment is omitted.

According to the twenty ninth embodiment, the same advantage as the first embodiment can be obtained.

### Thirtieth Embodiment

Next, a thirtieth embodiment of the present invention will be described.

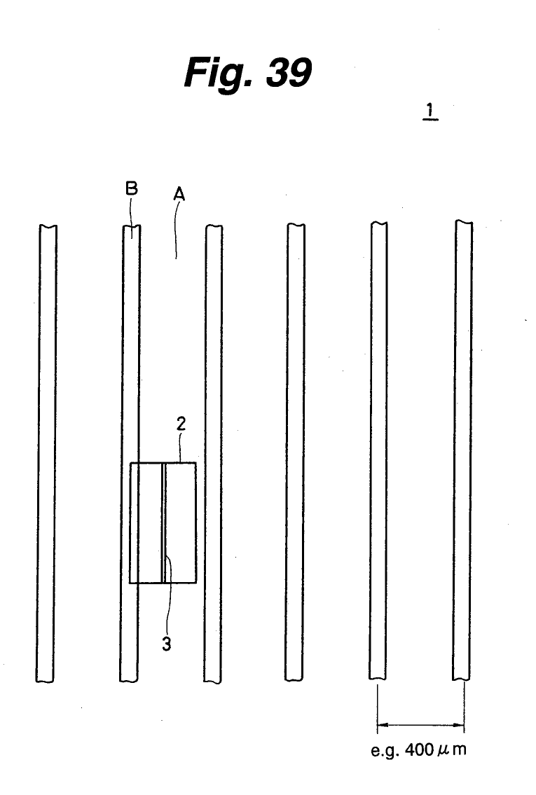

As shown in FIG. 39, according to the thirtieth embodiment, a GaN substrate 1 that is the same as the twenty ninth embodiment is used. However, unlike with the twenty ninth embodiment, one end plane that is in parallel with a laser stripe 3 passes through a region B. Another end plane passes through a position apart from a region B. In this case, a device region 2 does not substantially contain a region B.

Except for the foregoing portion, the thirtieth embodiment is the same as the twenty ninth embodiment and the first embodiment. Thus, the description of the other portions of the thirtieth embodiment is omitted.

According to the thirtieth embodiment, the same advantage as the first embodiment can be obtained.

### Thirty First Embodiment

Next, a thirty first embodiment of the present invention will be described.

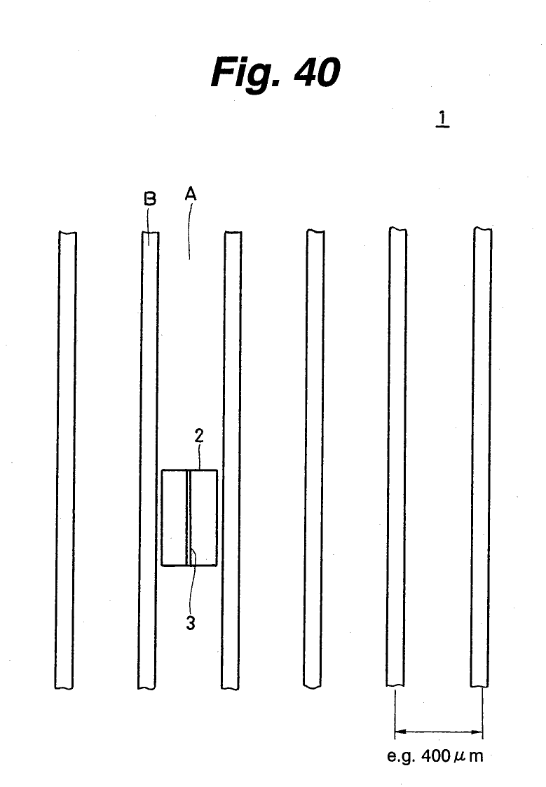

As shown in FIG. 40, according to the thirty first embodiment, a GaN substrate 1 that is the same as the twenty ninth embodiment is used. However, unlike with the twenty ninth embodiment, a device region 2 is confined so that a pair of end planes that are in parallel with a laser stripe 3 are positioned between regions B. The laser stripe 3 is positioned near the center of a region between the regions B. In this case, a device region 2 does not substantially contain the regions B.

Except for the foregoing portion, the thirty first embodiment is the same as the twenty ninth embodiment and the first embodiment. Thus, the description of the other portions of the thirty first embodiment is omitted.

According to the thirty first embodiment, the same advantage as the first embodiment can be obtained.

### Thirty Second Embodiment

Next, a thirty second embodiment will be described.

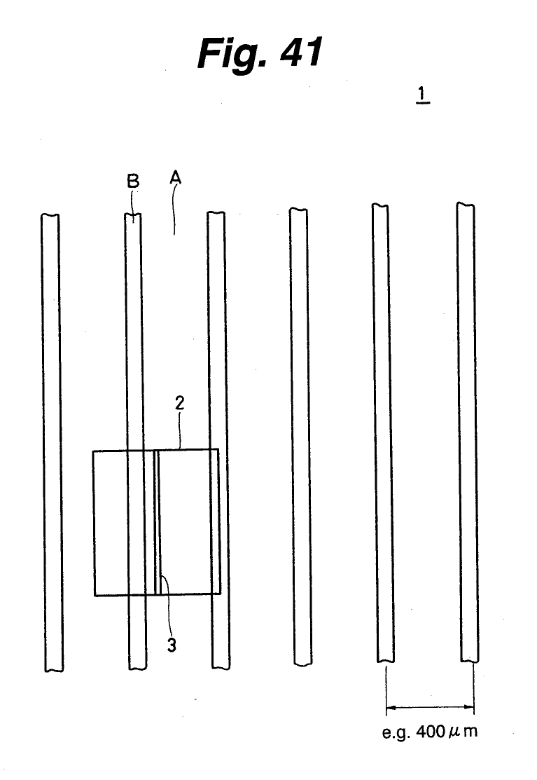

As shown in FIG. 41, according to the thirty second embodiment, a GaN substrate 1 that is the same as the twenty ninth embodiment is used. However, unlike with the twenty ninth embodiment, one end plane that is in parallel with a laser stripe 3 passes through a region B. Another end plane is positioned between the adjacent regions B. The laser stripe 3 passes through a position apart from the region B by 50 μm or greater. In this case, a device region 2 contains one region B.

Except for the foregoing portion, the thirty second embodiment is the same as the twenty ninth embodiment and the first embodiment. Thus, the description of the other portions of the thirty second embodiment is omitted.

According to the thirty second embodiment, the same advantage as the first embodiment can be obtained.

### Thirty Third Embodiment

Next, a thirty third embodiment of the present invention will be described.

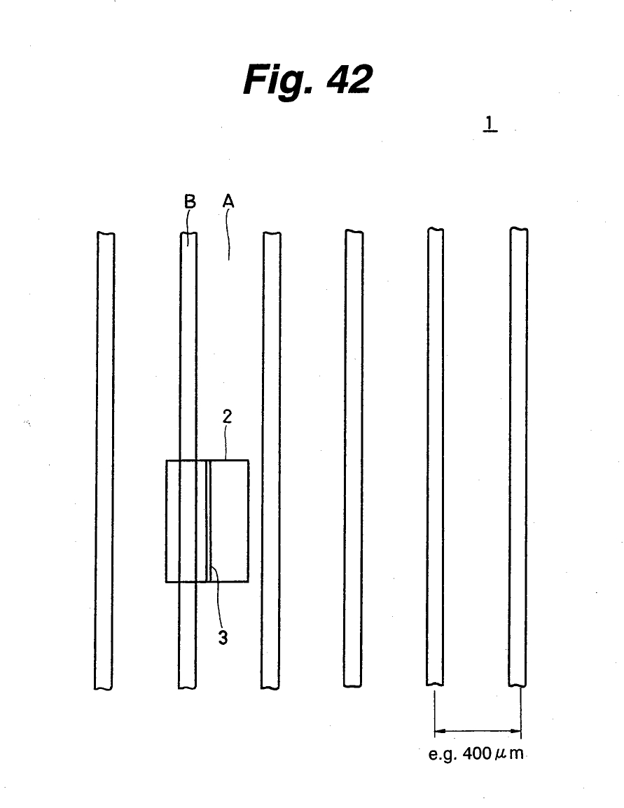

As shown in FIG. 42, according to the thirty third embodiment, a GaN substrate 1 that is the same as the twenty ninth embodiment is used. However, unlike with the twenty ninth embodiment, one end plane that is in parallel with a laser stripe 3 passes through a position apart from a region B. Another end plane passes through a position that is placed between the two adjacent regions B and that is apart from the region B by 50 μm or greater. In this case, a device region 2 contains one region B.

Except for the foregoing portion, the thirty third embodiment is the same as the twenty ninth embodiment and the first embodiment. Thus, the description of the other portions of the thirty third embodiment is omitted.

According to the thirty third embodiment, the same advantage as the first embodiment can be obtained.

### Thirty Fourth Embodiment

Next, a thirty fourth embodiment of the present invention will be described.

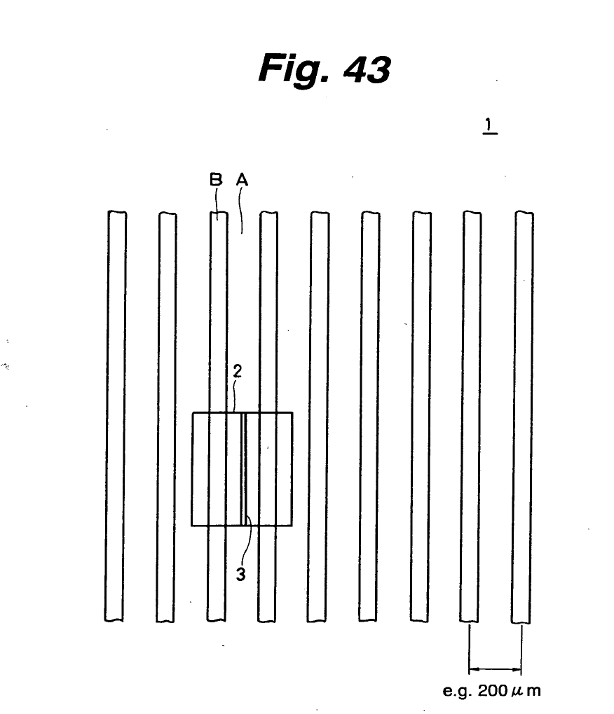

FIG. 43 is a plane view showing a GaN substrate 1 according to the thirty fourth embodiment. The GaN substrate 1 according to the thirty fourth embodiment is the same as the GaN substrate 1 according to the twenty ninth embodiment except that regions B of the GaN substrate 1 are periodically arranged at an interval of for example 200 μm. In this case, a device region 2 contains two regions B.

As shown in FIG. 43, according to the thirty fourth embodiment, a laser stripe 3 is positioned near the center of a region between two adjacent regions B. A pair of end planes that are in parallel with the laser stripe 3 are positioned near the centers of regions between two adjacent regions B on the left and right of the laser stripe 3.

Except for the foregoing portion, the thirty fourth embodiment is the same as the twenty ninth embodiment and the first embodiment. Thus, the description of the other portions of the thirty fourth embodiment is omitted.

According to the thirty fourth embodiment, the same advantage as the first embodiment can be obtained.

Although the present invention has been shown and described with respect to a best mode embodiment thereof, it should be understood by those skilled in the art that the foregoing and various other changes, omissions, and additions in the form and detail thereof may be made therein without departing from the spirit and scope of the present invention.

For example, numeric values, structures, substrates, materials, processes, and so forth of the foregoing embodiments are just examples. When necessary, different numeric values, structures, substrates, materials, processes, and so forth can be used.

In reality, in the foregoing embodiments, the present invention was applied to a method for producing a GaN type semiconductor laser having a SCH structure. In addition, the present invention can be applied to a method for producing a GaN type light emitting diode having a double heterostructure (DH). Moreover, the present invention can be also applied to a method for producing a GaN type light emitting diode. In addition, the present invention can be applied to an electron traveling device using a nitride type III-V group compound semiconductor such as a GaN type FET or a GaN type hetero-junction bipolar transistor (HBT).

According to the foregoing embodiments, the GaN substrate 1 may be disposed on a different type substrate such as a sapphire substrate.

In addition, according to the foregoing embodiments, the MOCVD method is used to grow a GaN type semiconductor layer. Alternatively, a GaN type semiconductor laser may be grown by hydride vapor phase epitaxial growth method, halide vapor phase epitaxial growth (HVPE) method, molecular ray epitaxy (MBE) method, or the like.

In addition, according to the foregoing embodiments, as a carrier gas with which a crystal is grown by the MOCVD method, H₂ gas is used. When necessary, another carrier gas for example a mixed gas of H₂ and N₂ or a mixed gas of He and Ar may be used.

In addition, according to the foregoing embodiment, end planes of a resonator are formed by cleaving. Alternatively, end planes of a resonator may be formed by a dry-etching method such as RIE.

As described above, according to the present invention, a nitride type III-V group compound semiconductor layer, a semiconductor layer, or a layer made of various types of materials that forms a light emitting device structure or a device structure is formed on a principal plane of a nitride type III-V group compound semiconductor substrate, a semiconductor substrate, or a layer made of various types of materials in such a manner that a first region does not directly contact second regions that have a higher average dislocation density, a higher average defect density, or worse crystallinity than the first region, the nitride type III-V group compound semiconductor layer, the semiconductor layer, or the layer made of the variety of materials that form the light emitting device structure or device structure can be prevented from being adversely affected by the second regions. Thus, a semiconductor device having good characteristics such as good light emitting characteristic, good reliability, and long life or various types of devices having good characteristics, good reliability, and long life can be accomplished.

What is claimed is:

1. A method for producing a semiconductor light emitting device, comprising the step of:
(a) growing a nitride type III-V group compound semiconductor layer that forms a light emitting device structure on a principal plane of a nitride type III-V group compound semiconductor substrate on which a plurality of second regions made of a crystal having a second average dislocation density are regularly arranged in a first region made of a crystal having a first average dislocation density so as to produce a semiconductor light emitting device, the second average dislocation density being greater than the first average dislocation density;
(b) coating the front surface of the second regions with a coating layer;
(c) removing the second regions from the principal plane of the nitride type III-V group compound semiconductor substrate for a predetermined depth,
wherein,
the coating step (b) is followed by the growing step (a), and
the nitride type III-V group compound semiconductor layer does not directly contact the second regions on the principal plane of the nitride type III-V group compound semiconductor substrate.

2. The method for producing the semiconductor light emitting device as set forth in claim 1, further comprising the step of:
(d) filling the removed portions of the second regions with the coating layer.

3. A method for producing a semiconductor light emitting device, comprising the step of:
(a) growing a nitride type III-V group compound semiconductor layer that forms a light emitting device structure on a principal plane of a nitride type III-V group compound semiconductor substrate on which a plurality of second regions made of a crystal having a second average dislocation density are regularly arranged in a first region made of a crystal having a first average dislocation density so as to produce a semiconductor light emitting device, the second average dislocation density being greater than the first average dislocation density,
wherein,
the nitride type III-V group compound semiconductor layer does not directly contact the second regions on the principal plane of the nitride type III-V group compound semiconductor substrate,
third regions are disposed between the first region and the second regions, the third regions having a third average dislocation density that is greater than the first average dislocation density and lower than the second average dislocation density, and
the nitride type III-V group compound semiconductor layer does not directly contact the second regions and the third regions on the principal plane of the nitride type III-V group compound semiconductor substrate.

5. The method for producing the semiconductor light emitting device as set forth in claim 4, further comprising the step of:
(b) removing at least part of the second regions and the third regions from the principal plane of the nitride type III-V group compound semiconductor substrate,
wherein,
the removing step (b) is followed by the growing step (a).
